(19) United States
(12) Patent Application Publication
(10) Pub. No.: US 2023/0090314 A1
(43) Pub. Date: Mar. 23, 2023

(54) SEMICONDUCTOR DEVICE

(71) Applicant: ROHM CO., LTD., Kyoto (JP)

(72) Inventor: Shusaku FUJIE, Kyoto (JP)

(73) Assignee: ROHM CO., LTD., Kyoto (JP)

(21) Appl. No.: 17/795,198

(22) PCT Filed: Feb. 1, 2021
(86) PCT No.: PCT/JP2021/003522

§ 371 Date: Jul. 25, 2022

(30) Foreign Application Priority Data
Feb. 14, 2020 (JP) 2020-023747

(51) Int. Cl. H01L 29/06; H01L 29/40

(52) U.S. Cl. CPC H01L 29/0634; H01L 29/405

(57) ABSTRACT

Provided is a semiconductor device including a semiconductor chip which has a main surface, a high potential region which is formed in a surface layer portion of the main surface, a low potential region which is formed in the surface layer portion of the main surface at an interval from the high potential region, a first conductive type drift region which is formed in a region between the high potential region and the low potential region in the surface layer portion of the main surface, and a first conductive type resurf region which is formed partially in a surface layer portion of the drift region such as to expose a part of a region which serves as a current path in the drift region from the main surface and which has an impurity concentration higher than that of the drift region.

### TECHNICAL FIELD

This application corresponds to Japanese Patent Application No. 2020-023747 filed on Feb. 14, 2020, in the Japan Patent Office, the entire disclosure of which is incorporated herein by reference.

The present invention relates to a semiconductor device.

### BACKGROUND ART

Patent Literature 1 discloses a semiconductor device which includes a semiconductor layer, a first electrode, a second electrode and a horizontal-type element. The first electrode is formed on a front surface of the semiconductor layer. The second electrode is formed on the front surface of the semiconductor layer at an interval from the first electrode. The horizontal-type element is formed in a region between the first electrode and the second electrode in a surface layer portion of the front surface of the semiconductor layer and electrically connected to the first electrode and the second electrode.

### CITATION LIST

### Patent Literature

Patent Literature 1: US Patent Application Publication No. 2013/075877.

### SUMMARY OF INVENTION

### Technical Problem

One embodiment of the present invention provides a semiconductor device capable of reducing on-resistance, while suppressing a decrease in withstand voltage.

### Solution to Problem

One embodiment of the present invention provides a semiconductor device including a semiconductor chip which has a main surface, a high potential region which is formed in a surface layer portion of the main surface, a low potential region which is formed in the surface layer portion of the main surface at an interval from the high potential region, a first conductive type drift region which is formed in a region between the high potential region and the low potential region in the surface layer portion of the main surface, and a first conductive type resurf region which is partially formed in a surface layer portion of the drift region such as to expose a part of a region which serves as a current path in the drift region from the main surface and which has an impurity concentration higher than that of the drift region. According to the semiconductor device, it is possible to reduce on-resistance, while suppressing a decrease in withstand voltage.

One embodiment of the present invention provides a semiconductor device including a semiconductor chip which has a main surface, a high potential region and a low potential region which are formed in a surface layer portion of the main surface at an interval from each other, a first conductive type drift region which is formed in a region between the high potential region and the low potential region in the surface layer portion of the main surface, a first conductive type resurf region which is formed as a line extending in a direction in which the high potential region and the low potential region oppose each other in a surface layer portion of the drift region such as to expose a part of a region which serves as a current path in the drift region from the main surface and which has an impurity concentration higher than that of the drift region, a field insulating film which covers the drift region and the resurf region, and a field electrode which is formed on the field insulating film and led around as a line such as to intersect the resurf region in a plan view. According to the semiconductor device, it is possible to reduce on-resistance, while suppressing a decrease in withstand voltage.

The aforementioned as well as yet other objects, features and effects of the present invention will be made clear by the following description of the embodiments with reference to the accompanying drawings.

### BRIEF DESCRIPTION OF DRAWINGS

FIG. 1 is a plan view showing a semiconductor chip of a semiconductor device according to a first embodiment of the present invention.

FIG. 2 is an enlarged view of a region II shown in FIG. 1.

FIG. 3 is an enlarged view of a region III shown in FIG. 2.

FIG. 4 is a partially-notched perspective cross-sectional view of the region III shown in FIG. 2.

FIG. 5 is a cross-sectional view along line V-V shown in FIG. 3.

FIG. 6 is a main part enlarged view showing a resurf region.

FIG. 7 is an actual measurement graph for describing on-resistance.

FIG. 8 is an actual measurement graph for describing a breakdown voltage.

FIG. 9 is an actual measurement graph for describing a gate threshold voltage.

FIG. 10 is a drawing which corresponds to FIG. 5 and a cross-sectional view for describing a semiconductor device according to a second embodiment of the present invention.

FIG. 11 is a drawing which corresponds to FIG. 5 and a cross-sectional view for describing a semiconductor device according to a third embodiment of the present invention.

FIG. 12 is a drawing which corresponds to FIG. 4 and a perspective cross-sectional view for describing a resurf region according to a first modified example.

FIG. 13 is a drawing which corresponds to FIG. 4 and a perspective cross-sectional view for describing a resurf region according to a second modified example.

FIG. 14 is a drawing which corresponds to FIG. 4 and a perspective cross-sectional view for describing a resurf region according to a third modified example.

FIG. 15 is a drawing which corresponds to FIG. 4 and a perspective cross-sectional view for describing a resurf region according to a fourth modified example.

### DESCRIPTION OF EMBODIMENTS

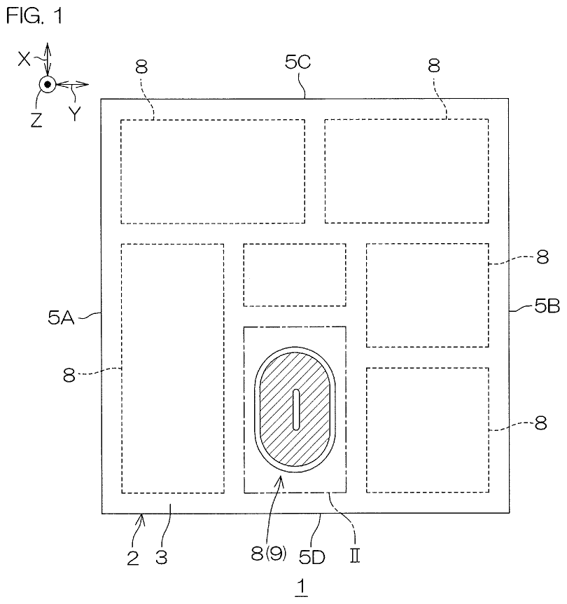

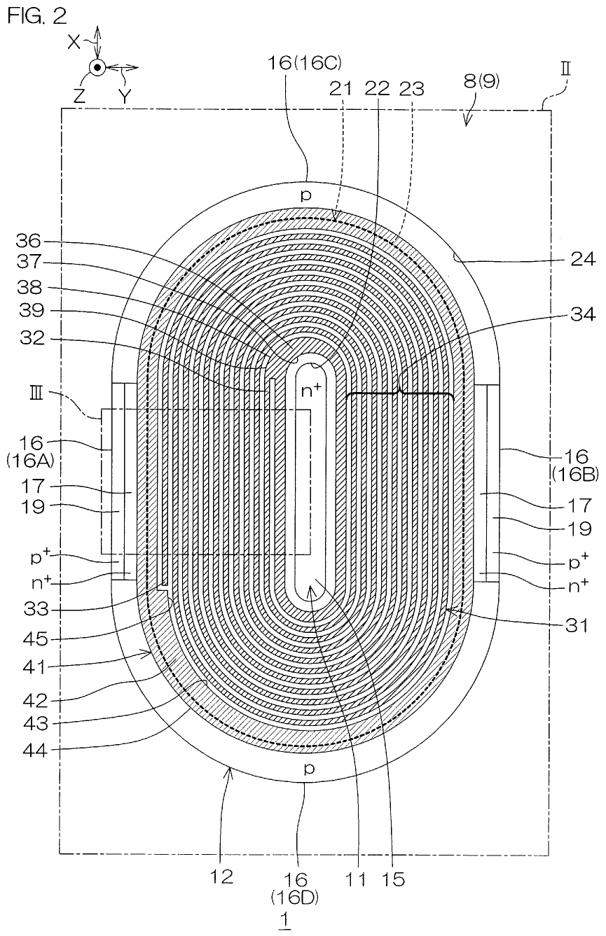

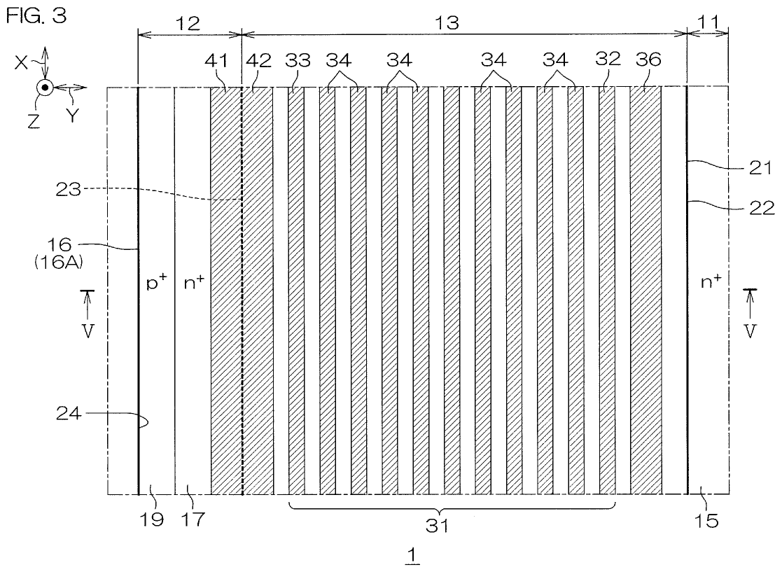

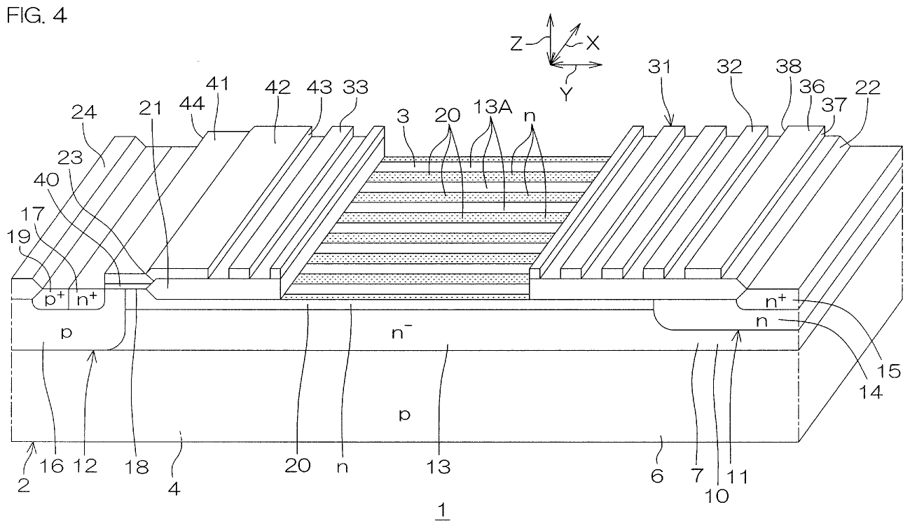

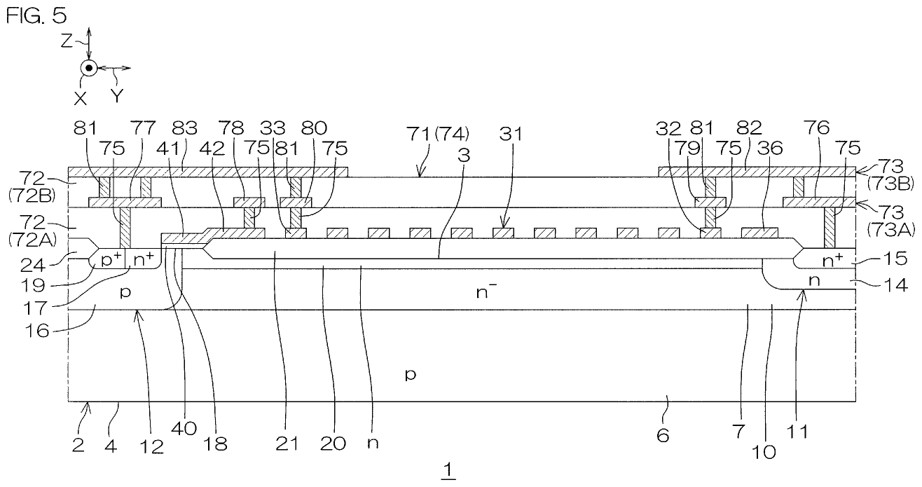

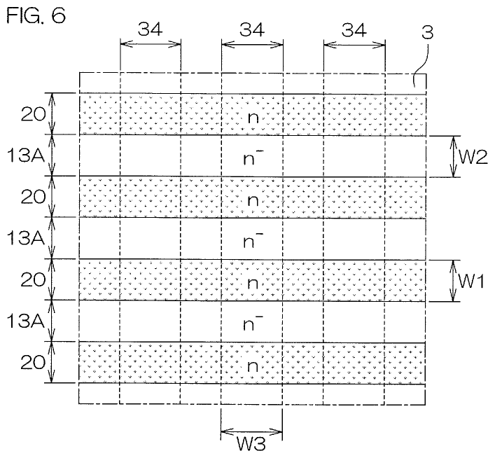

FIG. 1 is a plan view showing a semiconductor chip 2 of a semiconductor device 1 according to the first embodiment of the present invention. FIG. 2 is an enlarged view of the region II shown in FIG. 1. FIG. 3 is an enlarged view of the region III shown in FIG. 2. FIG. 4 is a partially-notched perspective cross-sectional view of the region III shown in FIG. 2. FIG. 5 is a cross-sectional view along line V-V shown in FIG. 3. FIG. 6 is a main part enlarged view showing a resurf region 20.

With reference to FIG. 1 to FIG. 6, the semiconductor device 1 includes a semiconductor chip 2 which is made of silicon and formed in a rectangular parallelepiped shape. The semiconductor chip 2 has a first main surface 3 on one side, a second main surface 4 on the other side and first to fourth side surfaces 5A to 5D which connect the first main surface 3 and the second main surface 4. The first main surface 3 and the second main surface 4 are formed in a quadrilateral shape in a plan view as viewed in a normal direction Z thereto (hereinafter, simply referred to as “in a plan view”).

The first to fourth side surfaces 5A to 5D include the first side surface 5A, the second side surface 5B, the third side surface 5C and the fourth side surface 5D. The first side surface 5A and the second side surface 5B extend in a first direction X and face each other in a second direction Y orthogonal to the first direction X. The third side surface 5C and the fourth side surface 5D extend in the second direction Y and face each other in the first direction X. In this embodiment, the semiconductor chip 2 has a laminated structure which includes a p-type semiconductor substrate 6 and an n-type epitaxial layer 7 that is formed on the semiconductor substrate 6.

The semiconductor substrate 6 forms the second main surface 4 and parts of the first to fourth side surfaces 5A to 5D. The semiconductor substrate 6 may have a p-type impurity concentration which is not less than 1.0×10¹³ cm⁻³ and not more than 1.0×10¹⁵ cm⁻³. A thickness of the semiconductor substrate 6 may be not less than 100 μm and not more than 500 μm. The epitaxial layer 7 forms the first main surface 3 and parts of the first to fourth side surfaces 5A to 5D.

The epitaxial layer 7 may have an n-type impurity concentration which exceeds the p-type impurity concentration of the semiconductor substrate 6. The n-type impurity concentration of the epitaxial layer 7 may be not less than 1.0×10¹⁴ cm⁻³ and not more than 1.0×10¹⁶ cm⁻³. The n-type impurity concentration of the epitaxial layer 7 is preferably not less than 1.0×10¹⁵ cm⁻³ and not more than 5.0×10¹⁵ cm⁻³. A thickness of the epitaxial layer 7 may be not less than 5 μm and not more than 20 μm.

The semiconductor device 1 includes a plurality of device regions 8 which are demarcated in the first main surface 3. The number and the arrangement of the plurality of device regions 8 are arbitrary. The plurality of device regions 8 each include a functional device which is formed by using the first main surface 3 and/or a surface layer portion of the first main surface 3. The functional device may include at least one of a semiconductor switching device, a semiconductor rectifying device and a passive device. The functional device may include a circuit network in which at least two of the semiconductor switching device, the semiconductor rectifying device and the passive device are combined.

The semiconductor switching device may include at least one of a MISFET (Metal Insulator Semiconductor Field Effect Transistor), a BJT (Bipolar Junction Transistor), an IGBT (Insulated Gate Bipolar Junction Transistor) and a JFET (Junction Field Effect Transistor). The semiconductor rectifying device may include at least one of a pn junction diode, a pin junction diode, a Zener diode, a Schottky barrier diode and a fast recovery diode. The passive device may include at least one of a resistor, a capacitor and an inductor.

The plurality of device regions 8 include an LDMIS region 9 in which an LDMISFET (Lateral Double diffused MISFET) as an example of the MISFET is formed (refer to the region II in FIG. 1). Hereinafter, a specific description will be given of a structure of the LDMIS region 9.

With reference to FIG. 2 to FIG. 5, the semiconductor device 1 includes an n-type impurity region 10 which is formed in the surface layer portion of the first main surface 3 in the LDMIS region 9. In this embodiment, the impurity region 10 is formed by utilizing a part of the epitaxial layer 7. Therefore, the impurity region 10 has an n-type impurity concentration which is equal to the n-type impurity concentration of the epitaxial layer 7. In this embodiment, the impurity region 10 is formed in an elliptical shape in a plan view. The impurity region 10 may be formed in a circular shape, an oval shape or a polygonal shape (for example, a quadrilateral shape).

The semiconductor device 1 includes a high potential region 11, a low potential region 12 and a drift region 13 which are formed in the surface layer portion of the first main surface 3 in the LDMIS region 9. The high potential region 11 is formed in a central portion of the impurity region 10. The low potential region 12 is formed in the surface layer portion of the first main surface 3 at an interval from the high potential region 11 and connected to the impurity region 10. The drift region 13 is formed in a region between the high potential region 11 and the low potential region 12 in the impurity region 10.

Specifically, the high potential region 11 includes an n-type well region 14 which is formed in a surface layer portion of the impurity region 10. The well region 14 has an n-type impurity concentration higher than the n-type impurity concentration of the impurity region 10. The n-type impurity concentration of the well region 14 may be not less than 1.0×10¹⁵ cm⁻³ and not more than 1.0×10¹⁸ cm⁻³. In this embodiment, the well region 14 is formed in an elliptical shape extending along the impurity region 10 in a plan view. The well region 14 may be formed in a circular shape, an oval shape or a polygonal shape (for example, a quadrilateral shape).

The high potential region 11 includes an n-type drain region 15 which is formed in a surface layer portion of the well region 14. The drain region 15 has an n-type impurity concentration higher than the n-type impurity concentration of the well region 14. The n-type impurity concentration of the drain region 15 may be not less than 1.0×10¹⁸ cm⁻³ and not more than 1.0×10²¹ cm⁻³. The drain region 15 is formed in an inward portion of the well region 14 at an interval from a peripheral edge of the well region 14. In this embodiment, the drain region 15 is formed in an elliptical shape extending along the well region 14 in a plan view. The drain region 15 may be formed in a circular shape, an oval shape or a polygonal shape (for example, quadrilateral shape).

Specifically, the low potential region 12 includes a p-type body region 16 which is formed adjacent to the impurity region 10 in the surface layer portion of the first main surface 3. The body region 16 may have a p-type impurity concentration which is not less than 1.0×10¹⁵ cm⁻³ and not more than 1.0×10¹³ cm⁻³. The body region 16 has a bottom portion which is connected to the semiconductor substrate 6 and fixes the semiconductor substrate 6 at the same potential. The body region 16 is formed in a band shape extending along the impurity region 10. Specifically, the body region 16 is formed in an annular shape (in this embodiment, in an elliptical annular shape) which surrounds the impurity region 10 and demarcates the impurity region 10 into a predetermined shape (in this embodiment, an elliptical shape).

The body region 16 includes a first rectilinear portion 16A, a second rectilinear portion 16B, a first curve portion 16C and a second curve portion 16D in a plan view. The first rectilinear portion 16A is formed in a region of the impurity region 10 on one side with respect to the second direction Y and extends in the first direction X. The second rectilinear portion 16B is formed in a region of the impurity region 10 on the other side such as to oppose the first rectilinear portion 16A across the impurity region 10 with respect to the second direction Y and extends in parallel with the first rectilinear portion 16A. With respect to the first direction X, a length of the first rectilinear portion 16A and that of the second rectilinear portion 16B are preferably not more than a length of the drain region 15.

The first curve portion 16C is formed in a band shape extending in a circular arc shape between one end of the first rectilinear portion 16A and one end of the second rectilinear portion 16B. The second curve portion 16D opposes the first curve portion 16C across the impurity region 10 and is formed in a band shape extending in a circular arc shape between the other end of the first rectilinear portion 16A and the other end of the second rectilinear portion 16B.

The low potential region 12 includes an n-type source region 17 which is formed in a surface layer portion of the body region 16 at an interval from the impurity region 10. The source region 17 is formed on the inner edge side (impurity region 10 side) of the body region 16 and defines a channel region 18 of the LDMISFET with the impurity region 10 (drift region 13). The source region 17 has an n-type impurity concentration higher than the n-type impurity concentration of the well region 14. The n-type impurity concentration of the source region 17 may be not less than 1.0×10¹⁸ cm⁻³ and not more than 1.0×10²¹ cm⁻³. The n-type impurity concentration of the source region 17 is preferably equal to the n-type impurity concentration of the drain region 15.

In this embodiment, the source region 17 is formed in a band shape having ends in a certain region of the body region 16 in a plan view. Specifically, the source region 17 is formed each in the first rectilinear portion 16A and the second rectilinear portion 16B at an interval from the first curve portion 16C and the second curve portion 16D. That is, the source region 17 is not formed in the first curve portion 16C and the second curve portion 16D of the body region 16. The source region 17 is formed in a band shape having ends extending along the first rectilinear portion 16A and the second rectilinear portion 16B in a plan view.

The source region 17 opposes the drain region 15 in the second direction Y and forms in the drift region 13 a current path extending in the second direction Y with the drain region 15. A length of the source region 17 with respect to the first direction X is preferably not more than a length of the drain region 15. As a matter of course, the source region 17 may be formed in an annular shape (specifically, in an elliptical annular shape) which surrounds the impurity region 10. That is, the source region 17 may be formed in the first curve portion 16C and the second curve portion 16D of the body region 16 as well.

The low potential region 12 includes a p-type contact region 19 which is formed in a region different from the source region 17 in the surface layer portion of the body region 16. The contact region 19 is formed on the outer edge side (on the opposite side of the impurity region 10) of the body region 16 and opposes the channel region 18 across the source region 17. The contact region 19 has a p-type impurity concentration higher than the p-type impurity concentration of the body region 16. The p-type impurity concentration of the contact region 19 may be not less than 1.0×10¹⁸ cm⁻³ and not more than 1.0×10²¹ cm⁻³.

In this embodiment, the contact region 19 is formed in a band shape having ends in a certain region of the body region 16 in a plan view. Specifically, the contact region 19 is formed each in the first rectilinear portion 16A and the second rectilinear portion 16B at an interval from the first curve portion 16C and the second curve portion 16D of the body region 16. That is, the contact region 19 is not formed in the first curve portion 16C and the second curve portion 16D of the body region 16. The contact region 19 is formed in a band shape having ends extending along the first rectilinear portion 16A and the second rectilinear portion 16B in a plan view.

The contact region 19 opposes the drain region 15 in the second direction Y. A length of the contact region 19 with respect to the first direction X is preferably not more than a length of the drain region 15. As a matter of course, the contact region 19 may be formed in an annular shape (specifically, in an elliptical annular shape) surrounding the impurity region 10. That is, the contact region 19 may be formed in the first curve portion 16C and the second curve portion 16D of the body region 16 as well.

The drift region 13 is constituted of a part of the impurity region 10. The drift region 13 forms a current path which connects the high potential region 11 and the low potential region 12. Specifically, the drift region 13 is defined in a region between the drain region 15 (well region 14) and the source region 17 (body region 16) in the impurity region 10. Thereby, the drift region 13 forms a current path which connects the drain region 15 and the source region 17.

The drift region 13 is formed in an annular shape (in this embodiment, in an elliptical annular shape) which surrounds the drain region 15. In this embodiment, the drift region 13 has a rectilinear portion which is demarcated by the first rectilinear portion 16A (second rectilinear portion 16B) of the body region 16 and a curve portion which is demarcated by the first curve portion 16C (second curve portion 16D) of the body region 16. A distance of the drift region 13 may be not less than 50 μm and not more than 200 μm. The distance of the drift region 13 is preferably formed by a fixed distance along an annular shape (in this embodiment, an elliptical annular shape).

With reference to FIG. 4 to FIG. 6, the semiconductor device 1 includes an n-type resurf region 20 which is partially formed in a surface layer portion of the drift region 13 such as to expose a part of the drift region 13 from the first main surface 3. The resurf region 20 has an n-type impurity concentration higher than that of the drift region 13. The n-type impurity concentration of the resurf region 20 may be not less than 1.0×10¹⁵ cm⁻³ and not more than 5.0×10¹⁶ cm⁻³.

The resurf region 20 preferably has an upper limit value which is 20 times larger than the n-type impurity concentration of the drift region 13. The n-type impurity concentration of the resurf region 20 is preferably more than 2.25×10¹⁵ cm⁻³ and not more than 3.25×10¹⁶ cm⁻³. The n-type impurity concentration of the resurf region 20 is particularly preferably not less than 1.25×10¹⁵ cm⁻³ and not more than 2.5×10¹⁶ cm⁻³. The n-type impurity concentration of the resurf region 20 is preferably less than the n-type impurity concentration of the well region 14.

In this embodiment, the plurality of resurf regions 20 are formed in the surface layer portion of the drift region 13 at an interval from each other. The plurality of resurf regions 20 are formed on the first main surface 3 side at an interval from a bottom portion of the drift region 13. Specifically, the plurality of resurf regions 20 are formed shallower than the well region 14 and formed deeper than the drain region 15. The plurality of resurf regions 20 oppose the semiconductor substrate 6 across a part of the drift region 13.

The plurality of resurf regions 20 extend as a line in a direction in which the high potential region 11 and the low potential region 12 oppose each other in a plan view and are formed in a striped shape, at an interval from each other in a direction orthogonal to the opposing direction. Thereby, the plurality of resurf regions 20 expose a part of the drift region 13 in a striped shape from the first main surface 3 in a plan view.

The plurality of resurf regions 20 are formed in a region between the drain region 15 and the body region 16 in the surface layer portion of the drift region 13. Specifically, the resurf regions 20 are formed in a region between the well region 14 and the body region 16. In this embodiment, the resurf regions 20 have one end portion which is connected to the well region 14 and the other end portion which is connected to the body region 16. Thereby, the resurf regions 20 form a current path that extends continuously in a region between the well region 14 and the body region 16.

The plurality of resurf regions 20 are formed in a rectilinear portion of the drift region 13 at an interval from a curve portion of the drift region 13. That is, the plurality of resurf regions 20 are not formed in a region between the drain region 15 and the first curve portion 16C (second curve portion 16D) of the body region 16. The plurality of resurf regions 20 are formed in a region between the drain region 15 and the first rectilinear portion 16A (second rectilinear portion 16B) of the body region 16.

It is preferable that the resurf regions 20 are formed partially in the surface layer portion of the drift region 13 such as to expose a part of a region which serves as a current path in the drift region 13 from the first main surface 3. That is, the plurality of resurf regions 20 are preferably formed only in a region sandwiched between the drain region 15 and the source region 17 in the surface layer portion of the drift region 13. Thereby, the resurf regions 20 form a current path which continuously extends in a region between the drain region 15 and the source region 17. Where the source region 17 (contact region 19) is formed in an annular shape which surrounds the impurity region 10, the plurality of resurf regions 20 may be formed in the curve portion of the drift region 13.

The semiconductor device 1 includes a plurality of drift line regions 13A (drift exposed regions) which are each demarcated in a region between the plurality of resurf regions 20 which are adjacent to each other in the surface layer portion of the drift region 13. The plurality of drift line regions 13A are constituted of a part of the drift region 13. The plurality of drift line regions 13A extend as a line in a direction in which the high potential region 11 and the low potential region 12 oppose each other in a plan view and are formed alternately with the plurality of resurf regions 20 in a direction orthogonal to the opposing direction.

An n-type impurity concentration of the drift line region 13A is less than the n-type impurity concentration of the resurf region 20. Therefore, a density of current which flows through the drift line region 13A is less than a density of current which flows through the resurf region 20. On the other hand, a depletion layer which expands with the drift line region 13A given as a starting point is larger than a depletion layer which expands with the resurf region 20 given as a starting point. Therefore, in the LDMIS region 9, a decrease in withstand voltage is suppressed by the drift line region 13A and on-resistance Ron is reduced by the resurf region 20.

With reference to FIG. 6, the plurality of resurf regions 20 each have a first width W1. The first width W1 is a width in a direction orthogonal to a direction in which the resurf regions 20 extend. The plurality of drift line regions 13A each have a second width W2. The second width W2 is a width in a direction orthogonal to a direction in which the drift line regions 13A extend.

A ratio of the first width W1 of the resurf region 20 in relation to the second width W2 of the drift line region 13A, W1/W2, may be not less than 0.5 and not more than 2.0 (0.5≤W1/W2≤2.0). The ratio of W1/W2 is preferably not more than 1.0 (0.5≤W/W2≤21.0). The ratio of W1/W2 is more preferably less than 1.0 (0.5≤W1/W2<1.0). That is, it is preferable that the resurf region 20 which is narrower than the drift line region 13A is formed.

The first width W1 may be not less than 1 μm and not more than 5 μm. The second width W2 may be not less than 1 μm and not more than 5 μm. The first width W1 and the second width W2 are each preferably not more than 3 μm. A total value of the first width W1 and the second width W2, W1+W2, is preferably not less than 3 μm and not more than 6 μm.

The plurality of resurf regions 20 are formed at a first occupying rate R1 in an opposing region between the drain region 15 and the source region 17. The first occupying rate R1 is a rate of the plurality of resurf regions 20 occupying the opposing region when the opposing region is given as “1.” The plurality of drift line regions 13A are formed at a second occupying rate R2 in the opposing region. The second occupying rate R2 is a rate of the plurality of drift line regions 13A occupying the opposing region when the opposing region is given as “1.”

The second occupying rate R2 may be not less than 0.5 times the first occupying rate R1 and not more than 2.0 times the first occupying rate R1 (0.5×R1≤R2≤2×R1). The second occupying rate R2 is preferably not less than the first occupying rate R1 (R1≤R2≤2×R1). The second occupying rate R2 is more preferably higher than the first occupying rate R1 (R1<R2≤2×R1).

The semiconductor device 1 includes a field insulating film 21 which is formed on the first main surface 3 such as to cover the drift region 13 and the plurality of resurf regions 20 in the LDMIS region 9. The field insulating film 21 contains a silicon oxide. In this embodiment, the field insulating film 21 is constituted of a LOCOS film formed by selectively oxidizing the first main surface 3. The field insulating film 21 may have a thickness of not less than 0.1 μm and not more than 2 μm.

Specifically, the field insulating film 21 is formed in an annular shape (in this embodiment, in an elliptical annular shape) which covers a region between the drain region 15 and the body region 16 in a plan view. The field insulating film 21 includes an inner edge portion 22 and an outer edge portion 23. In FIG. 2 and FIG. 3, the outer edge portion 23 of the field insulating film 21 is indicated by a dashed line. The inner edge portion 22 of the field insulating film 21 covers the well region 14 and exposes the drain region 15.

The outer edge portion 23 of the field insulating film 21 is formed on the high potential region 11 side at an interval from an inner edge of the body region 16 and exposes the body region 16, the source region 17 and the contact region 19. The outer edge portion 23 of the field insulating film 21 exposes a part of the drift region 13 and a part of the resurf region 20 from between the outer edge portion 23 and the inner edge of the body region 16.

The semiconductor device 1 includes an outer field insulating film 24 which is formed on the first main surface 3 such as to cover a region outside the LDMIS region 9. The outer field insulating film 24 has a thickness equal to that of the field insulating film 21 and includes the same material as that of the field insulating film 21. That is, in this embodiment, the outer field insulating film 24 is constituted of a LOCOS film. The outer field insulating film 24 covers an outer edge of the body region 16 and exposes the body region 16, the source region 17 and the contact region 19.

With reference to FIG. 4 and FIG. 5, the semiconductor device 1 includes a field electrode 31 which is led around as a line on the field insulating film 21. In this embodiment, the field electrode 31 contains a conductive polysilicon. In this embodiment, the field electrode 31 is constituted of a field resistance film which is electrically connected to the high potential region 11 and the low potential region 12. Specifically, the field electrode 31 is electrically connected to the drain region 15 and the body region 16 (the source region 17 and the contact region 19). The field electrode 31 forms a voltage drop toward the low potential region 12 from the high potential region 11 and suppress a bias of an electric field distribution in the drift region 13.

The field electrode 31 extends as a line intersecting the plurality of resurf regions 20 in a plan view and traverses the plurality of resurf regions 20 a plurality of times. Specifically, the field electrode 31 includes a portion which extends in a linear manner and a portion which extends in a curved manner. The field electrode 31 traverses the plurality of resurf regions 20 a plurality of times at the portion which extends in a linear manner. That is, when a single straight line is set which connects the high potential region 11 and the low potential region 12 in a plan view, the field electrode 31 traverses the straight line a plurality of times. The field electrode 31 opposes the drift region 13 across the field insulating film 21 in the portion which extends in a curved manner.

Specifically, the field electrode 31 surrounds the high potential region 11 a plurality of times in a plan view. More specifically, the field electrode 31 is formed in a spiral shape having an inner end portion 32 on the drain region 15 side, an outer end portion 33 on the body region 16 side and a spiral portion 34 which extends between the inner end portion 32 and the outer end portion 33 in a plan view. An arrangement of the inner end portion 32 and the outer end portion 33 is arbitrary.

In this embodiment, the inner end portion 32 is formed in a position which opposes the drain region 15 in the second direction Y. The inner end portion 32 may oppose the well region 14 across the field insulating film 21. In this embodiment, the outer end portion 33 is formed at a position which opposes the source region 17 in the second direction Y. The outer end portion 33 may oppose the drift line region 13A and the resurf region 20 across the field insulating film 21.

The spiral portion 34 is wound around outwardly from the inner end portion 32 toward the outer end portion 33 such as to surround the drain region 15 in a plan view and formed in an elliptical spiral shape. The spiral portion 34 opposes the drift line region 13A and the resurf region 20 across the field insulating film 21.

The field electrode 31 has a structure which forms a voltage drop in a spiral direction from the inner end portion 32 toward the outer end portion 33. That is, the field electrode 31 forms a potential gradient which is gradually decreased from the high potential region 11 toward the low potential region 12 by a potential according to the voltage drop with respect to a direction orthogonal to the spiral direction. The bias of the electric field distribution in the drift region 13 is suppressed by utilizing the above-described electrical properties of the field electrode 31.

With reference to FIG. 6, the field electrode 31 has a line width W3. The line width W3 is defined by a width in a direction orthogonal to an extending direction (that is, a spiral direction) of the field electrode 31. The line width W3 may be not less than 1 μm and not more than 5 μm. The line width W3 is preferably not more than 3 μm. The line width W3 may be equal to or larger than the first width W1 of the resurf region 20 (W1≤W3). The line width W3 may be equal to or larger than the second width W2 of the drift line region 13A (W2≤W3).

A resistance value of the field electrode 31 may be not less than 10 M and not more than 100 M. A pitch of the field electrode 31 may be not less than 1 μm and not more than 10 μm. The pitch of the field electrode 31 is preferably not less than 2 μm. The pitch of the field electrode 31 is defined by a distance between the mutually adjacent portions (that is, a winding pitch of the spiral portion 34). The number of turns of the field electrode 31 may be not less than 5 and not more than 20. The line width W3, the resistance value, the pitch and the number of turns of the field electrode 31 are arbitrary and adjusted according to an electric field to be relieved.

The semiconductor device 1 includes an inner field electrode 36 which is formed in a region between the field electrode 31 and the high potential region 11 (drain region 15) on the field insulating film 21. In this embodiment, the inner field electrode 36 is formed in a region surrounded by the field electrode 31 and fixed at the same potential as the high potential region 11 (drain region 15). The inner field electrode 36 has a thickness equal to that of the field electrode 31 and includes the same material as that of the field electrode 31 (that is, conductive polysilicon).

The inner field electrode 36 is formed in an annular shape (specifically, in an elliptical annular shape) which surrounds the drain region 15 at an interval from the drain region 15 and the field electrode 31. The inner field electrode 36 may oppose the well region 14 across the field insulating film 21. The inner field electrode 36 is preferably formed on the drain region 15 side at an interval from the plurality of resurf regions 20 in a plan view.

The inner field electrode 36 includes an inner edge portion 37 and an outer edge portion 38. The inner edge portion 37 of the inner field electrode 36 surrounds the drain region 15 at an interval from the drain region 15. The inner edge portion 37 of the inner field electrode 36 is preferably formed at a substantially fixed interval from the drain region 15.

The outer edge portion 38 of the inner field electrode 36 is formed at an interval from the field electrode 31. The outer edge portion 38 of the inner field electrode 36 is preferably formed at a substantially fixed interval from the field electrode 31. A distance between the inner field electrode 36 and the field electrode 31 is preferably equal to the pitch of the field electrode 31.

In this embodiment, the inner field electrode 36 is formed in an uneven width along a circumferential direction. Specifically, the inner field electrode 36 has a field protrusion portion 39 in the outer edge portion 38. The field protrusion portion 39 is led out toward the field electrode 31 such as to oppose a leading end of the inner end portion 32 in a spiral direction of the field electrode 31. The field protrusion portion 39 keeps a substantially constant distance between the inner field electrode 36 and the field electrode 31 and suppresses an uneven electric field due to the inner end portion 32 of the field electrode 31.

In this embodiment, the inner field electrode 36 is connected to the inner end portion 32 of the field electrode 31 and fixed at the same potential as the inner end portion 32. Specifically, the field protrusion portion 39 is connected to the inner end portion 32. Where the inner field electrode 36 and the inner end portion 32 can be fixed at the same potential, the inner field electrode 36 is not necessarily connected to the inner end portion 32. Further, whether the inner field electrode 36 is provided or not is arbitrary, and it may be removed if necessary.

A line width of the inner field electrode 36 may be not less than 1 μm and not more than 15 μm. The inner field electrode 36 is preferably formed wider than the field electrode 31. The line width of the inner field electrode 36 is preferably not less than 1.5 times and not more than 5 times the line width W3 of the field electrode 31. As a matter of course, the inner field electrode 36 having the line width of not more than the line width W3 may be formed.

With reference to FIG. 4 and FIG. 5, the semiconductor device 1 includes a gate insulating film 40 which covers the channel region 18 on the first main surface 3. In this embodiment, the gate insulating film 40 is constituted of a silicon oxide. The gate insulating film 40 is formed in a band shape extending along the field insulating film 21 in a plan view and exposes the body region 16, the source region 17 and the contact region 19.

In this embodiment, the gate insulating film 40 is formed in an annular shape (specifically, in an elliptical annular shape) which surrounds the field insulating film 21 in a plan view. The gate insulating film 40 has a thickness less than that of the field insulating film 21 and is connected to the field insulating film 21 (outer edge portion 23). Thereby, the gate insulating film 40 covers a portion which is exposed from between an inner edge of the body region 16 and the outer edge portion 23 of the field insulating film 21 in the drift region 13 (drift line region 13A) and the resurf region 20. A thickness of the gate insulating film 40 may be not less than 10 nm and not more than 200 nm.

The semiconductor device 1 includes a gate electrode 41 which is formed on the gate insulating film 40. The gate electrode 41 has a thickness equal to that of the field electrode 31 and includes the same material as that of the field electrode 31 (that is, conductive polysilicon). The gate electrode 41 opposes the channel region 18 across the gate insulating film 40. In this embodiment, the gate electrode 41 also opposes the drift region 13 (drift line region 13A) and the resurf region 20 across the gate insulating film 40. The gate electrode 41 is formed in a band shape extending along the field insulating film 21 in a plan view. In this embodiment, the gate electrode 41 is formed in an annular shape (specifically, in an elliptical annular shape) which surrounds the field insulating film 21 in a plan view.

The gate electrode 41 has a covering portion 42 which is led out on the field insulating film 21 from above the gate insulating film 40. The covering portion 42 is formed in an annular shape (specifically, in an elliptical annular shape) which surrounds the field electrode 31 at an interval from the field electrode 31. The covering portion 42 opposes the drift region 13 and the resurf region 20 across the field insulating film 21.

The gate electrode 41 includes an inner edge portion 43 and an outer edge portion 44. The inner edge portion 43 of the gate electrode 41 is formed by the covering portion 42 and traverses the drift line region 13A and the resurf region 20 in a plan view. The inner edge portion 43 of the gate electrode 41 is preferably formed at a substantially fixed interval from the field electrode 31. A distance between the gate electrode 41 and the field electrode 31 is preferably equal to the pitch of the field electrode 31. The outer edge portion 44 of the gate electrode 41 is formed in a region which overlaps the body region 16 in a plan view. The outer edge portion 44 of the gate electrode 41 is preferably formed at a substantially fixed interval from the outer edge portion 23 of the field insulating film 21.

In this embodiment, the gate electrode 41 is formed in an uneven width along a circumferential direction. In this embodiment, the gate electrode 41 has a gate protrusion portion 45 in the inner edge portion 43. The gate protrusion portion 45 is led out toward the field electrode 31 side such as to oppose a leading end of the outer end portion 33 in a spiral direction of the field electrode 31. The gate protrusion portion 45 keeps a substantially constant distance between the gate electrode 41 and the field electrode 31 and suppresses an uneven electric field due to the outer end portion 33 of the field electrode 31.

With reference to FIG. 4, the semiconductor device 1 includes an insulating layer 71 which is laminated on the first main surface 3 and covers the LDMIS region 9. The insulating layer 71 is constituted of a multilayered wiring structure 74 having a laminated structure in which a plurality of interlayer insulating layers 72 and a plurality of wiring layers 73 are alternately laminated. The interlayer insulating layer 72 means an insulating layer which is interposed between two wiring layers 73 which are adjacent to each other in an up/down direction. However, the lowermost interlayer insulating layer 72 of the plurality of interlayer insulating layers 72 means an insulating layer which is interposed between the semiconductor chip 2 and a first wiring layer 73.

FIG. 4 shows a portion in which, of the multilayered wiring structure 74, the first and the second interlayer insulating layers, 72A, 72B, and the first and the second wiring layers, 73A, 73B, are alternately laminated. The number of laminations in the interlayer insulating layer 72 and the wiring layer 73 is arbitrary and not limited to a particular number. The multilayered wiring structure 74 may have a laminated structure in which at least three interlayer insulating layers 72 and at least three wiring layers 73 are alternately laminated.

Each of the interlayer insulating layers 72 includes at least one of an SiO₂ film and an SiN film. Each of the interlayer insulating layers 72 may have a single layer structure constituted of an SiO₂ film or an SiN film. Each of the interlayer insulating layers 72 may have a laminated structure in which one or a plurality of SiO₂ films and/or one or a plurality of SiN films are laminated in an arbitrary order. Each of the wiring layers 73 may include at least one of an Al film, a Cu film, an AlSiCu alloy film, an AlSi alloy film and an AlCu alloy film.

The plurality of first wiring layers 73A are formed on the first interlayer insulating layer 72A. The plurality of first wiring layers 73A are each electrically connected to a corresponding connection target via one or a plurality of first via electrodes 75 which penetrate through the first interlayer insulating layer 72A. The first via electrode 75 may be a tungsten plug electrode. Specifically, the plurality of first wiring layers 73A include a first drain wiring 76, a first source wiring 77, a first gate wiring 78, an inner field wiring 79 and an outer field wiring 80.

The first drain wiring 76 is electrically connected to the drain region 15 via one or a plurality of first via electrodes 75. The first source wiring 77 is electrically connected to the source region 17 (the body region 16 and the contact region 19) via one or a plurality of first via electrodes 75. The first gate wiring 78 is electrically connected to the gate electrode 41 via one or a plurality of first via electrodes 75.

The inner field wiring 79 is electrically connected to the inner end portion 32 of the field electrode 31 via one or a plurality of first via electrodes 75. The inner field wiring 79 may be electrically connected to the inner field electrode 36 via one or a plurality of first via electrodes 75. The inner field wiring 79 may be formed integrally with the first drain wiring 76. The outer field wiring 80 is electrically connected to the outer end portion 33 of the field electrode 31 via one or a plurality of first via electrodes 75. The outer field wiring 80 may be formed integrally with the first source wiring 77.

The plurality of second wiring layers 73B are formed on the second interlayer insulating layer 72B. The plurality of second wiring layers 73B are each electrically connected to a corresponding connection target via one or a plurality of second via electrodes 81 which penetrate through the second interlayer insulating layer 72B. The second via electrode 81 may be a tungsten plug electrode. Specifically, the plurality of second wiring layers 73B include a second drain wiring 82, a second source wiring 83 and a second gate wiring (not shown).

The second drain wiring 82 is electrically connected to the first drain wiring 76 and the inner field wiring 79 via a plurality of second via electrodes 81. The second drain wiring 82 covers the drain region 15 and the inner field wiring 79 in a plan view. The second drain wiring 82 preferably covers an entire region of the drain region 15 and an entire region of the inner field wiring 79 in a plan view. The second drain wiring 82 is preferably led out to a position that opposes the inner field electrode 36 in a plan view. Further, the second drain wiring 82 is preferably led out to a position that opposes a portion of the field electrode 31 which forms the innermost peripheral portion in a plan view.

The second source wiring 83 is electrically connected to the first source wiring 77 and the outer field wiring 80 via a plurality of second via electrodes 81. The second source wiring 83 is formed in an annular shape extending along the body region 16 in a plan view. The second source wiring 83 preferably covers the gate electrode 41 and the outer field wiring 80 in a plan view.

The second drain wiring 82 preferably covers an entire region of the body region 16, an entire region of the gate electrode 41 and an entire region of the outer field wiring 80 in a plan view. Further, the second source wiring 83 is preferably led out to a position that opposes a portion of the field electrode 31 which forms the outermost peripheral portion in a plan view.

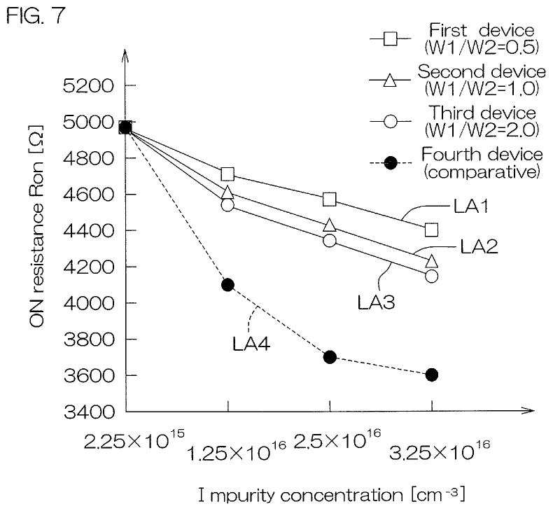

Hereinafter, with reference to FIG. 7 to FIG. 9, electrical characteristics of the semiconductor device 1 will be described. Here, as electrical characteristics of the semiconductor device 1, an on-resistance Ron, a breakdown voltage VB and a gate threshold voltage Vth were investigated. The breakdown voltage VB is a withstand voltage of the semiconductor device 1. In order to investigate the electrical characteristics of the semiconductor device 1, a first device, a second device, a third device and a fourth device were provided.

The first device is a semiconductor device 1 which has a structure in which a ratio of the first width W1 of the resurf region 20 in relation to the second width W2 of the drift line region 13A, W1/W2, is set at “0.5.” The second device is a semiconductor device 1 which has a structure in which the ratio of W1/W2 is set at “1.0.” The third device is a semiconductor device 1 which has a structure in which the ratio of W1/W2 is set at “2.0.” Here, the first width W1 and the second width W2 are each adjusted in a range of not less than 1 μm and not more than 3 μm. Further, a total value of the first width W1 and the second width W2, W1+W2, is each adjusted in a range of not less than 3 μm and not more than 6 μm.

The fourth device is a semiconductor device according to a comparative example. In the semiconductor device according to the comparative example, the resurf region 20 is formed across an entirety of a region which serves as a current path in the drift region 13, and no drift line region 13A is formed. That is, in the semiconductor device according to the comparative example, the resurf region 20 is formed across an entirety of an opposing region between the drain region 15 and the source region 17 in the surface layer portion of the drift region 13.

Further, here, an n-type impurity concentration of the resurf region 20 was adjusted to 1.25×10¹⁶ cm⁻³, 2.5×10¹⁶ cm⁻³ and 3.25×10¹⁶ cm⁻³ in each of the first to fourth devices and their electrical characteristics were investigated. An n-type impurity concentration of the drift region 13 (drift line region 13A) was 2.25×10¹⁵ cm⁻³.

FIG. 7 is an actual measurement graph for describing on-resistance Ron. The vertical axis indicates the on-resistance Ron [Ω]. The horizontal axis indicates the n-type impurity concentration [cm⁻³] of the resurf region 20, with the n-type impurity concentration (=2.25×10¹⁵ cm⁻³) of the drift region 13 (drift line region 13A) given as a reference.

FIG. 7 shows first to fourth line charts, LA1 to LA4. The first line chart LA1 is constituted of four square plot points, showing characteristics of the on-resistance Ron of the first device (W1/W2=0.5). The second line chart LA2 is constituted of four triangular plot points, showing characteristics of the on-resistance Ron of the second device (W1/W2=1.0). The third line chart LA3 is constituted of four circular plot points, showing characteristics of the on-resistance Ron of the second device (W1/W2=2.0). The fourth line chart LA4 is constituted of four filled-circular plot points, showing characteristics of the on-resistance Ron of the fourth device (comparative example).

With reference to the first to fourth line charts, LA1 to LA4, the on-resistance Ron decreased with formation of the resurf region 20 and further decreased with an increase in n-type impurity concentration of the resurf region 20. Further, a rate of decrease in on-resistance Ron upon an increase in n-type impurity concentration was increased in the ascending order of the first to fourth devices. That is, the rate of decrease in on-resistance Ron was increased with an increase in ratio of W1/W2, and the largest rate was found where the resurf region 20 was formed across an entirety of an opposing region between the drain region 15 and the source region 17.

Therefore, the n-type impurity concentration of the resurf region 20 is preferably set at a relatively high value. Further, the ratio of W1/W2 is preferably set at a relatively large value. That is, in order to reduce the on-resistance Ron, it is preferable to form the resurf region 20 which is relatively high in concentration and relatively large in width under conditions of being higher than the n-type impurity concentration of the drift region 13.

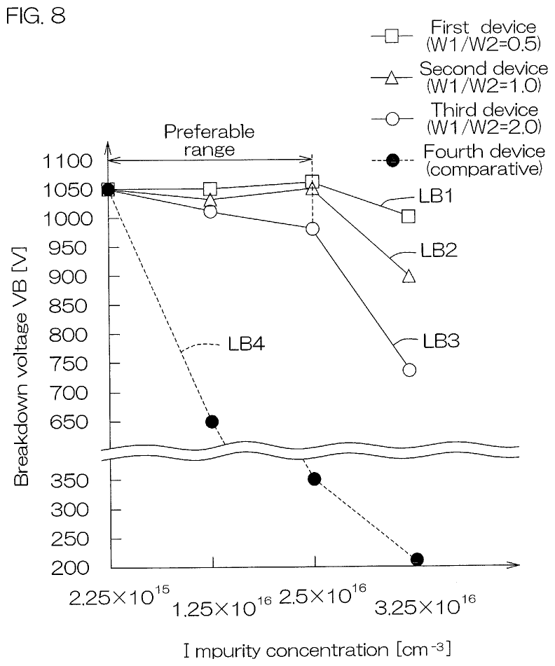

FIG. 8 is an actual measurement graph for describing the breakdown voltage VB. The vertical axis indicates the breakdown voltage VB [V]. The horizontal axis indicates the n-type impurity concentration [cm⁻³] of the resurf region 20, with the n-type impurity concentration (=2.25×10¹⁵ cm⁻³) of the drift region 13 (drift line region 13A) given as a reference.

FIG. 8 shows first to fourth line charts, LB1 to LB4. The first line chart LB1 is constituted of four square plot points, showing characteristics of the breakdown voltage VB of the first device (W1/W2=0.5). The second line chart LB2 is constituted of four triangular plot points, showing characteristics of the breakdown voltage VB of the second device (W1/W2=1.0). The third line chart LB3 is constituted of four circular plot points, showing characteristics of the breakdown voltage VB of the second device (W1/W2=2.0). The fourth line chart LB4 is constituted of four filled-circular plot points, showing characteristics of the breakdown voltage VB of the fourth device (comparative example).

With reference to the first to fourth line charts, LB1 to LB4, it was found that the breakdown voltage VB tends to decrease with formation of the resurf region 20. Further, the breakdown voltage VB decreased with an increase in n-type impurity concentration of the resurf region 20. A rate of decrease in breakdown voltage VB upon an increase in n-type impurity concentration was increased in the ascending order of the first to fourth devices. That is, the rate of decrease in breakdown voltage VB was increased with an increase in ratio of W1/W2, and a maximum rate was found where the resurf region 20 was formed across an entirety of an opposing region between the drain region 15 and the source region 17.

In particular, a significant decrease in breakdown voltage VB was found in the fourth device. In this respect, the breakdown voltage VB of the first to third devices was higher than the breakdown voltage VB of the fourth device at any n-type impurity concentration. Therefore, it is preferable that the resurf region 20 is formed partially in the surface layer portion of the drift region 13 such as to expose a part of a region which serves as a current path in the drift region 13 from the first main surface 3. Further, it is preferable that the resurf region 20 is not formed across an entirety of the region which serves as the current path in the drift region 13.

Further, the n-type impurity concentration of the resurf region 20 is preferably set at a relatively low value. Still further, the ratio of W1/W2 is preferably set at a relatively small value. That is, in order to improve the breakdown voltage VB, it is preferable to form the resurf region 20 which is relatively low in concentration and relatively small in width under conditions of being higher than the n-type impurity concentration of the drift region 13.

With reference to FIG. 7 and FIG. 8, the on-resistance Ron and the breakdown voltage VB have a contradictory relationship with each other in terms of the n-type impurity concentration of the resurf region 20. Specifically, an increase in n-type impurity concentration of the resurf region 20 can reduce the on-resistance Ron but results in a decrease in breakdown voltage VB. On the other hand, a decrease in n-type impurity concentration of the resurf region 20 results in elevation of the on-resistance Ron but can improve the breakdown voltage VB. The n-type impurity concentration of the resurf region 20 can be set at an arbitrary value in a range higher than the n-type impurity concentration of the drift region 13 (drift line region 13A) but is required to be adjusted in view of the on-resistance Ron and the breakdown voltage VB.

Similarly, the on-resistance Ron and the breakdown voltage VB have a contradictory relationship with each other in terms of the ratio of W1/W2. Specifically, an increase in ratio of W1/W2 can reduce the on-resistance Ron but results in a decrease in breakdown voltage VB. On the other hand, a decrease in ratio of W1/W2 results in elevation of the on-resistance Ron but can improve the breakdown voltage VB. Although the ratio of W1/W2 can be set at an arbitrary value, it is required to be adjusted in view of the on-resistance Ron and the breakdown voltage VB.

While the drift line region 13A has such properties that improve the breakdown voltage VB and elevate the on-resistance Ron, the resurf region 20 has such properties that reduce the on-resistance Ron and decrease the breakdown voltage VB. Therefore, the n-type impurity concentration of the resurf region 20 is brought close to the n-type impurity concentration of the drift region 13 (drift line region 13A), thus making it possible to reduce the on-resistance Ron, while suppressing a decrease in breakdown voltage VB.

From the results of the first to third devices, the n-type impurity concentration of the resurf region 20 is preferably adjusted such as to be more than 2.25×10¹⁵ cm⁻³ and not more than 3.25×10¹⁶ cm⁻³. Further, the ratio of W1/W2 is preferably adjusted such as to be not less than 0.5 and not more than 2.0. Thereby, it is possible to reduce the on-resistance Ron, while suppressing a decrease in breakdown voltage VB.

As apparent from the graph of FIG. 8, the breakdown voltages VB of the first to third devices decrease sharply when the n-type impurity concentration of the resurf region 20 exceeds 2.5×10¹⁶ cm⁻³. Therefore, the n-type impurity concentration of the resurf region 20 is particularly preferably adjusted such as to be not less than 1.25×10¹⁵ cm⁻³ and not more than 2.5×10¹⁶ cm⁻³. Thereby, it is possible to suppress appropriately a decrease in breakdown voltage VB.

Further, a rate of decrease in breakdown voltage VB increases with an increase in ratio of W1/W2. Therefore, the ratio of W1/W2 is preferably not less than 0.5 and less than 2.0. The ratio of W1/W2 is particularly preferably not less than 0.5 and not more than 1.0. Thereby, it is possible to appropriately reduce the on-resistance Ron, while appropriately suppressing a decrease in breakdown voltage VB.

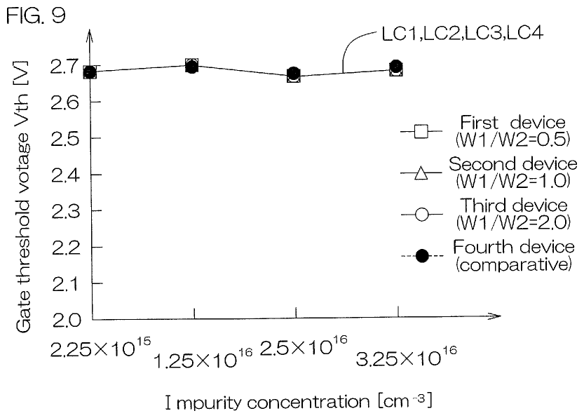

FIG. 9 is an actual measurement graph for describing the gate threshold voltage Vth. The vertical axis indicates the gate threshold voltage Vth [V]. The horizontal axis indicates the n-type impurity concentration [cm⁻³] of the resurf region 20, with the n-type impurity concentration (2.25×10¹⁵ cm⁻³) of the drift region 13 (drift line region 13A) given as a reference.

FIG. 9 shows first to fourth line charts LC1 to LC4. The first line chart LC1 is constituted of four square plot points, showing characteristics of the gate threshold voltage Vth of the first device (W1/W2=0.5). The second line chart LC2 is constituted of four triangular plot points, showing characteristics of the gate threshold voltage Vth of the second device (W1/W2=1.0). The third line chart LC3 is constituted of four circular plot points, showing characteristics of the gate threshold voltage Vth of the second device (W1/W2=2.0). The fourth line chart LC4 is constituted of four filled-circular plot points, showing characteristics of the gate threshold voltage Vth of the fourth device (comparative example).

With reference to the first to fourth line charts LC1 to LC4, the gate threshold voltages Vth of the first to fourth devices were substantially constant, irrespective of the n-type impurity concentration and the ratio of W1/W2 of the resurf region 20. Therefore, according to the first to third devices, it is possible to reduce the on-resistance Ron, while suppressing a change in gate threshold voltage Vth and a decrease in breakdown voltage VB.

As described so far, the semiconductor device 1 includes the semiconductor chip 2, the high potential region 11, the low potential region 12, the n-type drift region 13 and the n-type resurf region 20. The high potential region 11 is formed in the surface layer portion of first main surface 3 of the semiconductor chip 2. The low potential region 12 is formed in the surface layer portion of the first main surface 3 at an interval from the high potential region 11. The drift region 13 is formed in the region between the high potential region 11 and the low potential region 12 in the surface layer portion of the first main surface 3.

The resurf region 20 is formed partially in the surface layer portion of the drift region 13 such as to expose a part of the drift region 13 from the first main surface 3. Specifically, the resurf region 20 is formed such as to expose a part of a region which serves as a current path in the drift region 13 from the first main surface 3. The resurf region 20 has the n-type impurity concentration higher than that of the drift region 13.

A density of current which flows through the resurf region 20 is higher than a density of current which flows through the drift region 13. On the other hand, a depletion layer which expands, with the drift region 13 given as a starting point, is larger than a depletion layer which expands, with the resurf region 20 given as a starting point. Thereby, it is possible to suppress a decrease in breakdown voltage VB (withstand voltage) by the drift region 13 and reduce the on-resistance Ron by the resurf region 20.

The plurality of resurf regions 20 are preferably formed in the surface layer portion of the drift region 13 at an interval from each other. According to this structure, it is possible to reduce the on-resistance Ron by the plurality of resurf regions 20. The resurf regions 20 preferably extend as a line in a direction in which the high potential region 11 and the low potential region 12 oppose each other. According to this structure, it is possible to reduce the on-resistance Ron in a current path which connects as a line the high potential region 11 and the low potential region 12.

The plurality of resurf regions 20 are particularly preferably formed in a striped shape extending in the opposing direction and expose a part of the drift region 13 in a striped shape from the first main surface 3. In this case, the plurality of drift line regions 13A extending in a striped shape in the opposing direction are demarcated between the plurality of resurf regions 20 which are adjacent to each other. The plurality of drift line regions 13A are formed alternately with the plurality of resurf regions 20. According to this structure, a region which suppresses a decrease in withstand voltage and a region which reduces the on-resistance Ron are formed alternately in the surface layer portion of the drift region 13. Therefore, it is possible to suppress appropriately a decrease in withstand voltage and appropriately reduce the on-resistance Ron.

The semiconductor device 1 further includes the n-type impurity region 10 which is formed in the surface layer portion of the first main surface 3. The high potential region 11 includes the n-type drain region 15 which is formed in the surface layer portion of the impurity region 10. The low potential region 12 includes the p-type body region 16 which is formed adjacent to the impurity region 10 in the surface layer portion of the first main surface 3 and the n-type source region 17 which is formed in the surface layer portion of the body region 16 at an interval from the impurity region 10.

The drift region 13 is formed in the region between the drain region 15 and the source region 17 in the impurity region 10. The resurf region 20 is formed in the region between the drain region 15 and the source region 17 in the surface layer portion of the drift region 13. According to this structure, it is possible to reduce the on-resistance Ron in a current path which connects the drain region 15 and the source region 17.

The resurf region 20 is preferably formed only in the region which is sandwiched between the drain region 15 and the source region 17 in the drift region 13. According to this structure, the resurf region 20 relatively low in resistance is not formed outside a region sandwiched between the drain region 15 and the source region 17. Therefore, it is possible to appropriately suppress a flow of undesired current outside the region sandwiched between the drain region 15 and the source region 17.

The high potential region 11 may include the n-type well region 14 which is formed in the surface layer portion of the impurity region 10 and the drain region 15 which is formed in the surface layer portion of the well region 14 at an interval from a peripheral edge of the well region 14. In this case, the resurf region 20 may be formed in the region between the well region 14 and the source region 17 in the surface layer portion of the drift region 13. According to this structure, it is possible to appropriately suppress a flow of undesired current outside the region sandwiched between the well region 14 and the source region 17. In this case, the resurf region 20 is preferably connected to one of or both of the well region 14 and the body region 16 (preferably both of them).

The semiconductor device 1 further includes the field insulating film 21 and the field electrode 31. The field insulating film 21 covers the drift region 13 and the resurf region 20 on the first main surface 3. The field electrode 31 is led around as a line on the field insulating film 21 and traverses the resurf region 20 in a plan view. According to this structure, it is possible to suppress an electric field concentration in the drift region 13 and the resurf region 20 by the field electrode 31. Thereby, it is possible to improve the withstand voltage.

In this case, the field electrode 31 preferably traverses the resurf region 20 a plurality of times in a plan view. The field electrode 31 more preferably surrounds the high potential region 11 a plurality of times. According to this structure, it is possible to appropriately suppress the electric field concentration in the drift region 13 and the resurf region 20.

The field electrode 31 is preferably constituted of the field resistance film which is electrically connected to the high potential region 11 and the low potential region 12. According to this structure, an electric field can be appropriately distributed in the drift region 13 by utilizing the voltage drop in the field electrode 31. Thereby, it is possible to appropriately suppress the electric field concentration in the drift region 13 and the resurf region 20.

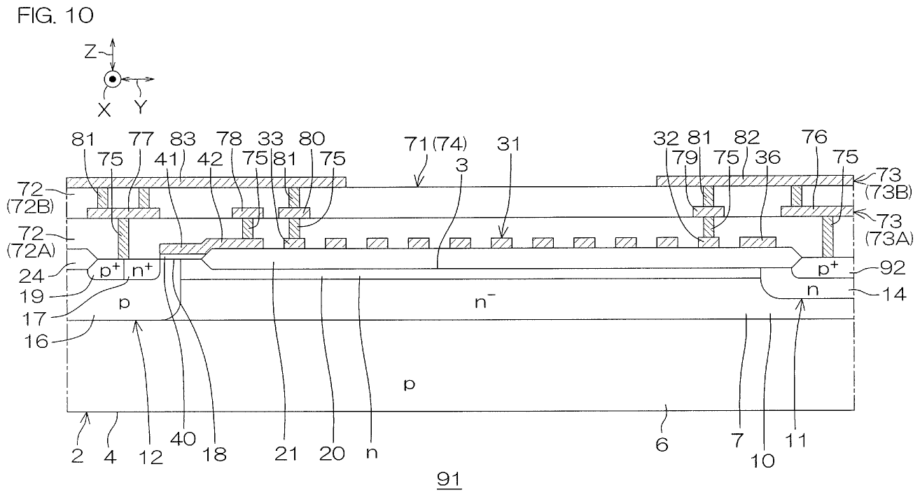

FIG. 10 is a drawing which corresponds to FIG. 5 and a cross-sectional view for describing a semiconductor device 91 according to the second embodiment of the present invention. Hereinafter, a structure which corresponds to the structure described for the semiconductor device 1 is given the same reference signs and a description thereof will be omitted.

The high potential region 11 according to the semiconductor device 91 includes a p-type collector region 92 in place of the drain region 15. The semiconductor device 91 can thus provide an IGBT in place of the LDMISFET. In this case, the “source” of the LDMISFET is read as an “emitter” of the IGBT. Further, the “drain” of the LDMISFET is read as a “collector” of the IGBT. Even where the IGBT is adopted in place of the LDMISFET, it is possible to provide the same effects as those described for the semiconductor device 1.

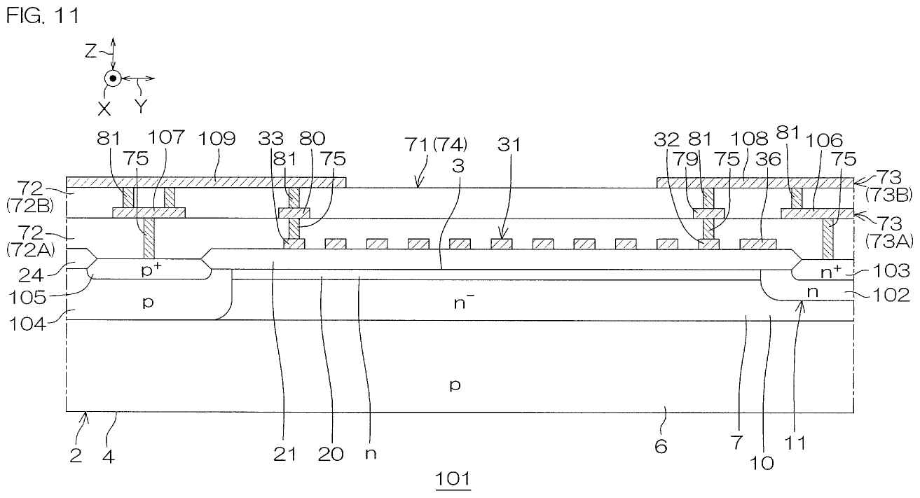

FIG. 11 is a drawing which corresponds to FIG. 5 and a cross-sectional view for describing a semiconductor device 101 according to the third embodiment of the present invention. Hereinafter, a structure which corresponds to the structure described for the semiconductor device 1 is given the same reference signs and a description thereof will be omitted.

The high potential region 11 according to the semiconductor device 101 includes an n-type cathode well region 102 in place of the well region 14 and an n-type cathode region 103 in place of the drain region 15. Further, the low potential region 12 according to the semiconductor device 101 includes a p-type anode well region 104 in place of the body region 16 and a p-type anode region 105 in place of the source region 17 and the contact region 19. The drift region 13 according to the semiconductor device 101 is formed in a region between the cathode well region 102 (cathode region 103) and the anode well region 104 (anode region 105).

The semiconductor device 101 does not have the gate insulating film 40 or the gate electrode 41. The cathode well region 102 and the cathode region 103 are formed respectively in the same manner as those of the well region 14 and the drain region 15 according to the first embodiment. The anode well region 104 is formed in the same manner as that of the body region 16 according to the first embodiment.

The anode region 105 is formed in a surface layer portion of the anode well region 104. The anode region 105 has a p-type impurity concentration higher than a p-type impurity concentration of the anode well region 104. The p-type impurity concentration of the anode region 105 may be not less than 1.0×10¹⁸ cm⁻³ and not more than 1.0×10²¹ cm⁻³.

In this embodiment, the anode region 105 is formed each in the first rectilinear portion 16A and the second rectilinear portion 16B at an interval from the first curve portion 16C and the second curve portion 16D of the anode well region 104 (refer to FIG. 2 as well). That is, the anode region 105 is not formed in the first curve portion 16C or the second curve portion 16D of the anode well region 104. The anode region 105 is formed in a band shape having ends extending along the first rectilinear portion 16A and the second rectilinear portion 16B in a plan view.

Thereby, the anode region 105 opposes the cathode region 103 in the second direction Y and forms, in the drift region 13, a current path along the second direction Y with the cathode region 103. With respect to the first direction X, a length of the anode region 105 is preferably less than a length of the cathode region 103. As a matter of course, the anode region 105 may be formed in an annular shape (specifically, in an elliptical annular shape) which surrounds an impurity region 10. That is, the anode region 105 may be formed also in the first curve portion 16C and the second curve portion 16D of the anode well region 104.

The semiconductor device 101 includes the resurf region 20 which is formed in the surface layer portion of the drift region 13. The resurf region 20 according to the semiconductor device 101 is formed in the same manner as that of the resurf region 20 according to the first embodiment. That is, in this embodiment, the plurality of resurf regions 20 are formed in the surface layer portion of the drift region 13 at an interval from each other.

The plurality of resurf regions 20 are formed on the first main surface 3 side at an interval from the bottom portion of the drift region 13. Specifically, the plurality of resurf regions 20 are formed shallower than the cathode well region 102 and formed deeper than the cathode region 103. The plurality of resurf regions 20 oppose the semiconductor substrate 6 across a part of the drift region 13.

The plurality of resurf regions 20 extend as a line in a direction in which the high potential region 11 and the low potential region 12 oppose each other in a plan view and are formed in a striped shape in a direction orthogonal to the opposing direction at an interval from each other. Thereby, the plurality of resurf regions 20 expose, from the first main surface 3, a part of the drift region 13 in a striped shape in a plan view.

The plurality of resurf regions 20 are formed in a region between the cathode region 103 and the anode well region 104 in the surface layer portion of the drift region 13. Specifically, the plurality of resurf regions 20 are formed in a region between the cathode well region 102 and the anode well region 104. In this embodiment, the resurf region 20 has one end portion which is connected to the cathode well region 102 and the other end portion which is connected to the anode well region 104. Thereby, the resurf regions 20 form a current path which extends continuously in a region between the cathode well region 102 and the anode well region 104.

The plurality of resurf regions 20 are formed in the rectilinear portion of the drift region 13 at an interval from the curve portion of the drift region 13. That is, the plurality of resurf regions 20 are not formed in a region between the cathode region 103 and the first curve portion 16C (second curve portion 16D) of the anode well region 104. The plurality of resurf regions 20 are formed in a region between the cathode region 103 and the first rectilinear portion 16A (second rectilinear portion 16B) of the anode well region 104.

The plurality of resurf regions 20 are formed only in a region which is sandwiched between the cathode region 103 and the anode region 105 in the surface layer portion of the drift region 13. Thereby, the resurf regions 20 form a current path which extends continuously in a region between the cathode region 103 and the anode region 105. Where the anode region 105 is formed in an annular shape which surrounds the impurity region 10, the plurality of resurf regions 20 may be formed in the curve portion of the drift region 13. The other constitutions of the plurality of resurf regions 20 are the same as those of the first embodiment and, therefore, a specific description will be omitted.

The semiconductor device 101 includes the plurality of drift line regions 13A (drift exposed regions) which are each demarcated in the region between the plurality of resurf regions 20 which are adjacent to each other in the surface layer portion of the drift region 13. A constitution of the plurality of drift line regions 13A is the same as that of the first embodiment and, therefore, a specific description will be omitted.

The first wiring layer 73A according to the semiconductor device 101 includes a first cathode wiring 106 and a first anode wiring 107 in place of the first drain wiring 76, the first source wiring 77 and the first gate wiring 78. The first cathode wiring 106 and the first anode wiring 107 are formed respectively in the same manner as those of the first drain wiring 76 and the first source wiring 77 according to the first embodiment.

A second wiring layer 73B according to the semiconductor device 101 includes a second cathode wiring 108 and a second anode wiring 109 in place of the second drain wiring 82, the second source wiring 83 and the second gate wiring (not shown). The second cathode wiring 108 and the second anode wiring 109 are formed respectively in the same manner as those of the second drain wiring 82 and the second source wiring 83 according to the first embodiment.

As described so far, the semiconductor device 101 can provide a diode in place of the LDMISFET. Even where the diode is adopted in place of the LDMISFET, it is possible to provide the same effects as those described for the semiconductor device 1. The diode according to the semiconductor device 101 can be used as a reflux diode which is reverse-parallel connected to a semiconductor switching device such as a MISFET (for example, the LDMISFET according to the first embodiment) and an IGBT (for example, the IGBT according to the second embodiment).

The embodiments of the present invention can be implemented in other embodiments.

In each of the aforementioned embodiments, a description has been given of an example in which the field electrode 31 constituted of the field resistance film is formed. However, the field electrode 31 in an electrically floating state may be formed. In this case, the plurality of field electrodes 31 which surround concentrically the high potential region 11 a plurality of times may be formed. In this case, the inner field electrode 36 may be removed.

The diode according to the third embodiment may be formed in the same semiconductor chip 2 (first main surface 3) as the LDMISFET according to the first embodiment. In this case, the LDMISFET according to the first embodiment is formed in one device region 8 (LDMIS region 9), and the diode according to the third embodiment is formed in the other device region 8. Further, in this case, the diode may be reverse-parallel connected to the LDMISFET as a reflux diode.

The diode according to the third embodiment may be formed in the same semiconductor chip 2 (first main surface 3) as the IGBT according to the second embodiment. In this case, the IGBT according to the second embodiment is formed in one device region 8, and the diode according to the third embodiment is formed in the other device region 8. Further, in this case, the diode may be reverse-parallel connected to the IGBT as a reflux diode.

In each of the aforementioned embodiments, the resistant field electrode 31 may be used as a current monitor for detecting a current which flows between the high potential region 11 and the low potential region 12. The current which flows between the high potential region 11 and the low potential region 12 is detected, for example, from a voltage drop of the field electrode 31 and a current which flows through the field electrode 31. According to this structure, it is possible to appropriately distribute an electric field by the field electrode 31 and enhance the convenience of the semiconductor device 1, 91 or 101 by functions of the current monitor.

In each of the aforementioned embodiments, a constitution in which a conductive type of each semiconductor region is reversed may be adopted. That is, a p-type portion may be given as an n-type, and an n-type portion may be given as a p-type.

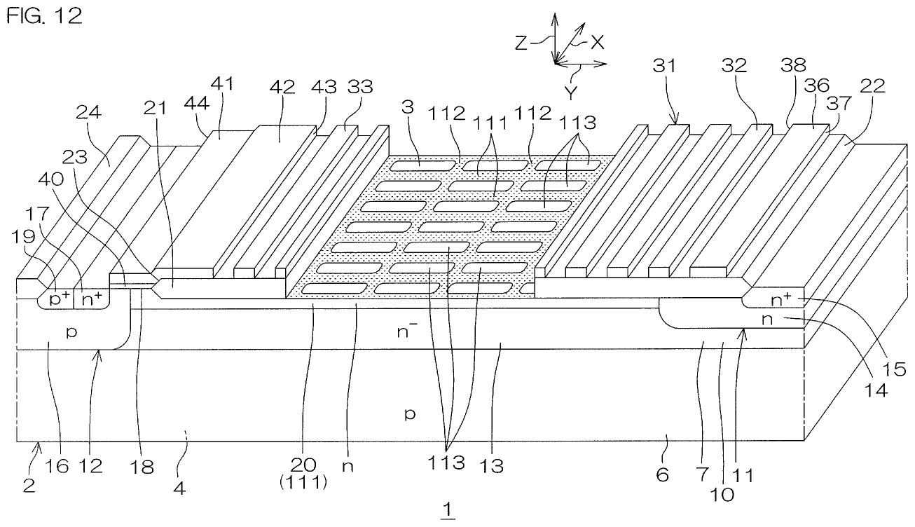

In each of the aforementioned embodiments, a description has been given of an example in which the plurality of resurf regions 20 extending in a striped shape are formed. However, the resurf regions 20 shown in FIG. 12 to FIG. 15 may be formed.

FIG. 12 is a drawing which corresponds to FIG. 4 and a perspective cross-sectional view for describing the resurf region 20 according to the first modified example. Hereinafter, a structure which corresponds to the structure described for the semiconductor device 1 will be given the same reference signs and a description thereof will be omitted.

The resurf region 20 according to the first modified example is formed in a lattice shape having a plurality of crossings in a plan view. Specifically, the resurf region 20 includes a plurality of first regions 111 and a plurality of second regions 112. The plurality of first regions 111 extend in a striped shape in a direction in which the high potential region 11 and the low potential region 12 oppose each other (second direction Y). The plurality of second regions 112 extend in a striped shape in a direction orthogonal to the opposing direction (first direction X) and each intersect the plurality of first regions 111 in a cross shape.

In the surface layer portion of the drift region 13, a plurality of divided regions 113 which are constituted of a part of the drift region 13 are demarcated by the resurf region 20. The plurality of divided regions 113 corresponds to a structure in which the drift line region 13A according to the first embodiment is divided into a plurality of portions by the plurality of second regions 112.

The plurality of divided regions 113 are arrayed in a matrix shape, at an interval from each other in the first direction X and in the second direction Y in a plan view. In this example, the plurality of divided regions 113 are each formed in a band shape extending in the second direction Y in a plan view. A planar shape of each of the plurality of divided regions 113 is arbitrary and may be formed in a quadrilateral shape, a circular shape, an oval shape or an elliptical shape.

As described so far, even where the resurf region 20 according to the first modified example is formed, it is possible to provide the same effects as those described for the semiconductor device 1. The resurf region 20 according to the first modified example is also applicable to the aforementioned second and third embodiments.

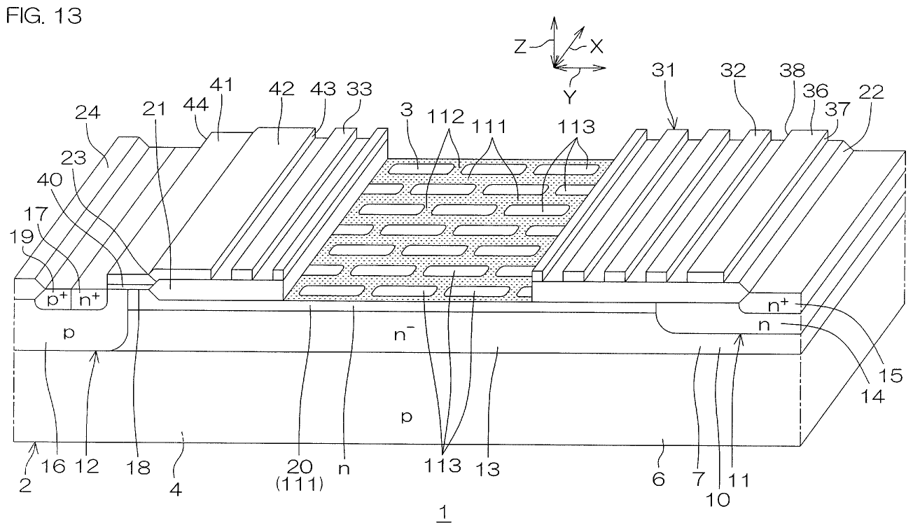

FIG. 13 is a drawing which corresponds to FIG. 4 and a perspective cross-sectional view for describing the resurf region 20 according to the second modified example. Hereinafter, a structure which corresponds to the structure described for the semiconductor device 1 is given the same reference signs and a description thereof will be omitted.

The resurf region 20 according to the second modified example is formed in a lattice shape having a plurality of T-letter junctions in a plan view. Specifically, the resurf region 20 includes a plurality of first regions 111 and a plurality of second regions 112. The plurality of first regions 111 extend in a striped shape in a direction (second direction Y) in which the high potential region 11 and the low potential region 12 oppose each other. The plurality of second regions 112 are formed, at an interval from each other in the opposing direction, in a region between the plurality of mutually adjacent first regions 111 and connect each of the plurality of mutually adjacent first region sill in a T-letter shape.

In the surface layer portion of the drift region 13, a plurality of divided regions 113 which are constituted of a part of the drift region 13 are demarcated by the resurf region 20. The plurality of divided regions 113 correspond to a structure in which the drift line region 13A according to the first embodiment is divided into a plurality of portions by the plurality of second regions 112.

The plurality of divided regions 113 are arrayed in a staggered form, at an interval from each other in the first direction X and in the second direction Y, in a plan view. In this example, the plurality of divided regions 113 are each formed in a band shape extending in the second direction Y in a plan view. A planar shape of each of the plurality of divided regions 113 is arbitrary and may be formed in a quadrilateral shape, a circular shape, an oval shape or an elliptical shape.

As described so far, even where the resurf region 20 according to the second modified example is formed, it is possible to provide the same effects as those described for the semiconductor device 1. The resurf region 20 according to the second modified example is also applicable to the aforementioned second and third embodiments.

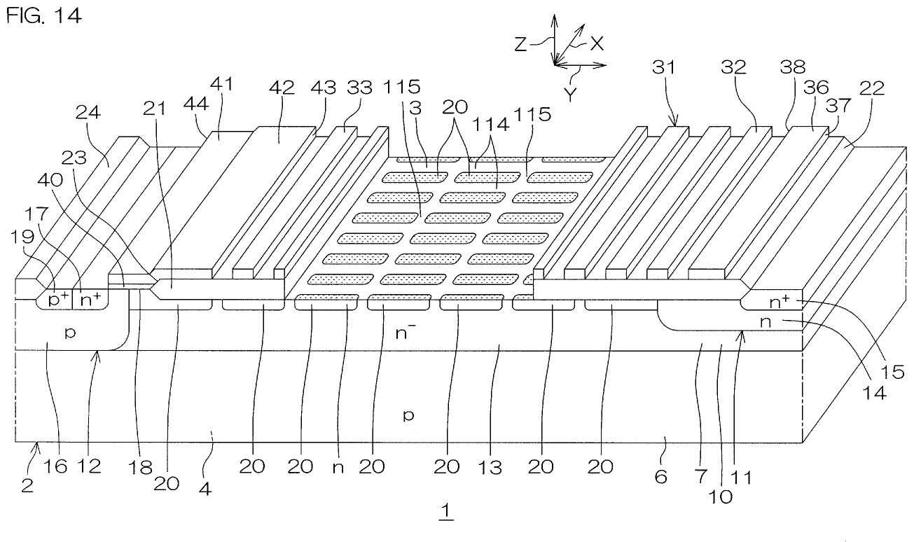

FIG. 14 is a drawing which corresponds to FIG. 4 and a perspective cross-sectional view for describing the resurf region 20 according to the third modified example. Hereinafter, a structure which corresponds to the structure described for the semiconductor device 1 is given the same reference signs and a description thereof will be omitted.

In the third modified example, the plurality of resurf regions 20 are formed in a matrix shape, at an interval from each other in a direction (second direction Y) in which a high potential region 11 and a low potential region 12 oppose each other and in a direction (first direction X) orthogonal to the opposing direction in a plan view. In this example, the plurality of resurf regions 20 are each formed in a band shape extending in the second direction Y in a plan view. A planar shape of each of the plurality of resurf regions 20 is arbitrary and may be formed in a quadrilateral shape, a circular shape, an oval shape or an elliptical shape.

In the surface layer portion of the drift region 13, a drift line region 13A which is constituted of a part of the drift region 13 is demarcated by the plurality of resurf regions 20. The drift line region 13A is demarcated in a lattice shape having a plurality of crossings. That is, the drift line region 13A includes a plurality of first line regions 114 and a plurality of second line regions 115 which form the crossings. The plurality of first line regions 114 extend in a striped shape in the opposing direction (second direction Y). The plurality of second line regions 115 extend in a striped shape in the orthogonal direction (first direction X) and intersect individually the plurality of first line regions 114 in a cross shape.

As described so far, even where the resurf region 20 according to the third modified example is formed, it is possible to provide the same effects as those described for the semiconductor device 1. However, in the third modified example, the plurality of resurf regions 20 are formed across a part of the drift region 13 at an interval from each other. Thus, the structure of the semiconductor device 1 is preferable in terms of reducing the on-resistance Ron. The resurf region 20 according to the third modified example is also applicable to the aforementioned second and third embodiments.

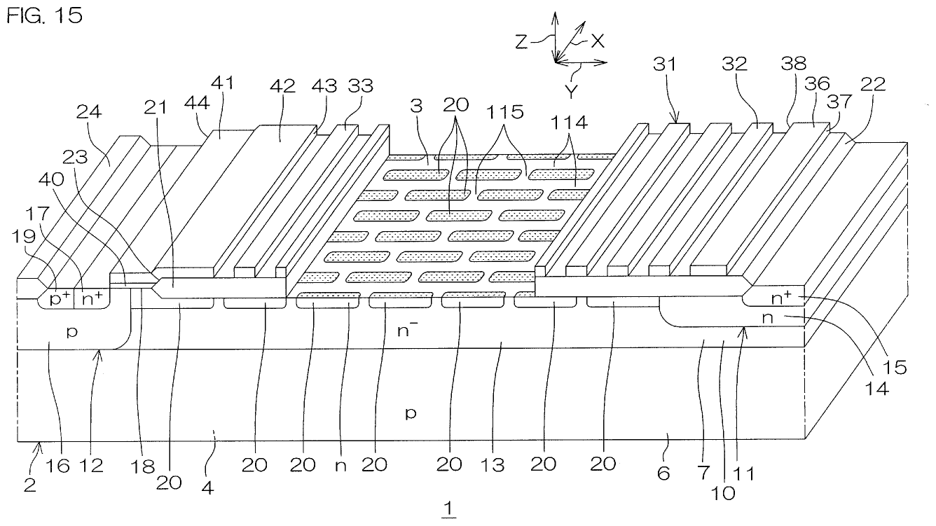

FIG. 15 is a drawing which corresponds to FIG. 4 and a perspective cross-sectional view for describing the resurf region 20 according to the fourth modified example. Hereinafter, a structure which corresponds to the structure described for the semiconductor device 1 is given the same reference signs and a description thereof will be omitted.

In the fourth modified example, the plurality of resurf regions 20 are each formed in a staggered form, at an interval from each other in a direction (second direction Y) in which the high potential region 11 and the low potential region 12 oppose each other and in a direction (first direction X) orthogonal to the opposing direction in a plan view. In this example, the plurality of resurf regions 20 are each formed in a band shape extending in the second direction Y in a plan view. A planar shape of each of the plurality of resurf regions 20 is arbitrary and may be formed in a quadrilateral shape, a circular shape, an oval shape or an elliptical shape.

In the surface layer portion of the drift region 13, a drift line region 13A which is constituted of a part of the drift region 13 is demarcated by the plurality of resurf regions 20. The drift line region 13A is demarcated in a lattice shape having a plurality of T-letter junctions. That is, the drift line region 13A includes a plurality of first line regions 114 and a plurality of second line regions 115 which form the T-letter junctions. The plurality of first line regions 114 extend in a striped shape in the opposing direction (second direction Y). The plurality of second line regions 115 are formed in a region between the plurality of mutually adjacent first line regions 114, at an interval from each other in the opposing direction, and each connect the plurality of mutually adjacent first line regions 114 in a T-letter shape.

As described so far, even where the resurf region 20 according to the fourth modified example is formed, it is possible to provide the same effects as those described for the semiconductor device 1. However, in the fourth modified example, the plurality of resurf regions 20 are formed across a part of the drift region 13 at an interval from each other. Therefore, the structure of the semiconductor device 1 is preferable in terms of reducing the on-resistance Ron. The resurf region 20 according to the fourth modified example is also applicable to the aforementioned second and third embodiments.

The aforementioned semiconductor devices 1, 91, 101 can be assembled into a power module which is used in an inverter circuit that drives an electric motor used as a power source for, for example, automobiles (including electric vehicles), trains, industrial robots, air conditioners, air compressors, electric fans, vacuum cleaners, dryers and refrigerators. The aforementioned semiconductor devices 1, 91, 101 can also be assembled into a power module which is used in an inverter circuit for solar cells, wind power generators and other electric power plants. Further, the aforementioned semiconductor devices 1, 91, 101 can be assembled into a circuit module which is used for analog control power sources and digital control power sources, etc.

Examples of features extracted from the present description and drawings are shown below. The following [A1] to [A19] and [B1] to [B20] are to provide a semiconductor device capable of suppressing a decrease in withstand voltage and reducing on-resistance. Although alphanumeric characters within parentheses in the following express corresponding constituent elements, etc., in the embodiments described above, these are not meant to limit the scopes of respective clauses to the embodiments.

[A1] A semiconductor device (1, 91, 101) comprising: a semiconductor chip (2) which has a main surface (3); a high potential region (11) which is formed in a surface layer portion of the main surface (3); a low potential region (12) which is formed in the surface layer portion of the main surface (3) at an interval from the high potential region (11); a first conductive type drift region (13) (13) which is formed in a region between the high potential region (11) and the low potential region (12) in the surface layer portion of the main surface (3); and a first conductive type resurf region (20) which is partially formed in a surface layer portion of the drift region (13) such as to expose a part of a region which serves as a current path in the drift region (13) from the main surface (3) and which has an impurity concentration higher than that of the drift region (13). According to this semiconductor device (1, 91, 101), it is possible to reduce on-resistance (Ron), while suppressing a decrease in withstand voltage (VB).

[A2] The semiconductor device (1, 91, 101) according to A1, wherein the resurf region (20) is formed as a line extending in a direction in which the high potential region (11) and the low potential region (12) oppose each other.

[A3] The semiconductor device (1, 91, 101) according to A1 or A2, wherein the plurality of resurf regions (20) are formed in the surface layer portion of the drift region (13) at an interval from each other.

[A4] The semiconductor device (1, 91, 101) according to A3, wherein the plurality of resurf regions (20) are formed in a striped shape extending in a direction in which the high potential region (11) and the low potential region (12) oppose each other and expose a part of the drift region (13) in a striped shape from the main surface (3).

[A5] The semiconductor device (1, 91, 101) according to any one of A1 to A4, further comprising: a field insulating film (21) which covers the drift region (13) and the resurf region (20) on the main surface (3); and a field electrode (31) which is led around as a line on the field insulating film (21) and traverses the resurf region (20) in a plan view.

[A6] The semiconductor device (1, 91, 101) according to A5, wherein the field electrode (31) traverses the resurf region (20) a plurality of times in a plan view.

[A7] The semiconductor device (1, 91, 101) according to A5 or A6, wherein the field electrode (31) surrounds the high potential region (11) a plurality of times.

[A8] The semiconductor device (1, 91, 101) according to any one of A5 to A7, wherein the field electrode (31) is constituted of a field resistance film which is electrically connected to the high potential region (11) and the low potential region (12).

[A9] The semiconductor device (1) according to any one of A1 to A8, wherein the high potential region (11) includes a first conductive type drain region (15) which is formed in the surface layer portion of the main surface (3), the low potential region (12) includes a second conductive type body region (16) which is formed in the surface layer portion of the main surface (3) and a first conductive type source region (17) which is formed in a surface layer portion of the body region (16), the drift region (13) is formed in a region between the drain region (15) and the body region (16) in the surface layer portion of the main surface (3), and the resurf region (20) is formed in a region between the drain region (15) and the source region (17) in the surface layer portion of the drift region (13).

[A10] The semiconductor device (1) according to A9, wherein the resurf region (20) is connected to the body region (16).

[A11] The semiconductor device (1) according to A9 or A10, wherein the high potential region (11) includes a first conductive type well region (14) which is formed in the surface layer portion of the main surface (3) and the drain region (15) which is formed in a surface layer portion of the well region (14), and the resurf region (20) is formed in a region between the well region (14) and the source region (17) in the surface layer portion of the drift region (13).

[A12] The semiconductor device (1) according to A11, wherein the resurf region (20) is connected to the well region (14).

[A13] The semiconductor device (1) according to any one of A9 to A12, wherein the resurf region (20) is formed only in a region sandwiched between the source region (17) and the drift region (13) in the drift region (13).

[A14] The semiconductor device (1) according to any one of A9 to A13, wherein the body region (16) surrounds the drain region (15), and the source region (17) is formed in a shape having ends in the surface layer portion of the body region (16).

[A15] The semiconductor device (1) according to any one of A9 to A14, further comprising: a channel region (18) which is formed between the drift region (13) and the source region (17) in the surface layer portion of the body region (16); a gate insulating film (40) which covers the channel region (18) on the main surface (3); and a gate electrode (41) which is formed on the gate insulating film (40).

[A16] The semiconductor device (1, 91, 101) according to A15, wherein the gate insulating film (40) covers the drift region (13) and the resurf region (20).

[A17] A semiconductor device (1, 91, 101) comprising: a semiconductor chip (2) which has a main surface (3); a high potential region (11) and a low potential region (12) which are formed in a surface layer portion of the main surface (3) at an interval from each other; a first conductive type drift region (13) which is formed in a region between the high potential region (11) and the low potential region (12) in the surface layer portion of the main surface (3); a first conductive type resurf region (20) which is formed as a line extending in a direction in which the high potential region (11) and the low potential region (12) oppose each other in the surface layer portion of the drift region (13) such as to expose a part of a region which serves as a current path in the drift region (13) from the main surface (3) and which has an impurity concentration higher than that of the drift region (13); a field insulating film (21) which covers the drift region (13) and the resurf region (20); and a field electrode (31) which is formed on the field insulating film (21) and led around as a line such as to intersect the resurf region (20) in a plan view.

[A18] The semiconductor device (1, 91, 101) according to A17, wherein the field electrode (31) is constituted of a field resistance film which is electrically connected to the high potential region (11) and the low potential region (12).

[A19] The semiconductor device (1, 91, 101) according to A17 or A18, wherein the field electrode (31) is orthogonal to the resurf region (20) in a plan view.

[B1] A semiconductor device (101) comprising: a semiconductor chip (2) which has a main surface (3); a first conductive type cathode region (103) which is formed in a surface layer portion of the main surface (3); a second conductive type anode region (105) which is formed in the surface layer portion of the main surface (3) at an interval from the cathode region (103); a first conductive type drift region (13) which is formed in a region between the cathode region (103) and the anode region (105) in the surface layer portion of the main surface (3); and a first conductive type resurf region (20) which is formed partially in a surface layer portion of the drift region (13) such as to expose a part of a region which serves as a current path in the drift region (13) from the main surface (3) and which has an impurity concentration higher than that of the drift region (13). According to this semiconductor device (101), it is possible to reduce on-resistance (Ron), while suppressing a decrease in withstand voltage (VB).

[B2] The semiconductor device (101) according to B1, wherein a high potential is to be applied to the cathode region (103), and a low potential is to be applied to the anode region (105).

[B3] The semiconductor device (101) according to B1 or B2, wherein the drift region (13) has an impurity concentration less than that of the cathode region (103).

[B4] The semiconductor device (101) according to any one of B1 to B3, wherein the resurf region (20) is formed as a line extending in a direction in which the cathode region (103) and the anode region (105) oppose each other.

[B5] The semiconductor device (101) according to any one of B1 to B4, wherein the plurality of resurf regions (20) are formed in the surface layer portion of the drift region (13) at an interval from each other.

[B6] The semiconductor device (101) according to B5, wherein the plurality of resurf regions (20) are formed in a striped shape extending in a direction in which the cathode region (103) and the anode region (105) oppose each other and expose a part of the drift region (13) in a striped shape from the main surface (3).

[B7] The semiconductor device (101) according to B6, wherein the plurality of resurf regions (20) demarcate a plurality of drift exposed regions (13A) extending in a striped shape in the opposing direction in the main surface (3).

[B8] The semiconductor device (101) according to any one of B1 to B7, further comprising: a field insulating film (21) which covers the drift region (13) and the resurf region (20) on the main surface (3); and a field electrode (31) which is led around as a line on the field insulating film (21) and traverses the resurf region (20) in a plan view.

[B9] The semiconductor device (101) according to B8, wherein the field electrode (31) traverses the resurf region (20) a plurality of times in a plan view.

[B10] The semiconductor device (101) according to B8 or B9, wherein the field electrode (31) surrounds the cathode region (103) a plurality of times.

[B11] The semiconductor device (101) according to any one of B8 to B10, wherein the field electrode (31) is constituted of a field resistance film which is electrically connected to the cathode region (103) and the anode region (105).

[B12] The semiconductor device (101) according to any one of B1 to B11, wherein the resurf region (20) is formed only in a region which is sandwiched between the cathode region (103) and the anode region (105) in the drift region (13).

[B13] The semiconductor device (101) according to any one of B1 to B12, further comprising: a first conductive type impurity region (11) which is formed in the surface layer portion of the main surface (3); a first conductive type cathode well region (102) which is formed in a surface layer portion of the impurity region (11); and a second conductive type anode well region (104) which is formed adjacent to the impurity region (11) in the surface layer portion of the main surface (3); wherein the cathode region (103) is formed in a surface layer portion of the cathode well region (102), the anode region (105) is formed in a surface layer portion of the anode well region (104), the drift region (13) is formed in a region between the cathode well region (102) and the anode well region (104), and the resurf region (20) is formed in a region between the cathode well region (102) and the anode well region (104) in the surface layer portion of the drift region (13).

[B14] The semiconductor device (101) according to B13, wherein the cathode region (103) has an impurity concentration higher than that of the cathode well region (102), and the anode region (105) has an impurity concentration higher than that of the anode well region (104).

[B15] The semiconductor device (101) according to B13 or B14, wherein the resurf region (20) is connected to the cathode well region (102).

[B16] The semiconductor device (101) according to any one of B13 to B15, wherein the resurf region (20) is connected to the anode well region (104).

[B17] The semiconductor device (101) according to any one of B13 to B16, wherein the anode well region (104) surrounds the impurity region (11) and the anode region (105) is formed in a band shape having ends extending along the impurity region (11).

[B18] A semiconductor device (101) comprising: a semiconductor chip (2) which has a main surface (3); a first conductive type cathode region (103) and a second conductive type anode region (105) which are formed in a surface layer portion of the main surface (3) at an interval from each other; a first conductive type drift region (13) which is formed in a region between the cathode region (103) and the anode region (105) in the surface layer portion of the main surface (3); a first conductive type resurf region (20) which is formed as a line extending in a direction in which the cathode region (103) and the anode region (105) oppose each other in a surface layer portion of the drift region (13) such as to expose a part of the drift region (13) from the main surface (3) and which has an impurity concentration higher than that of the drift region (13); a field insulating film (21) which covers the drift region (13) and the resurf region (20); and a field electrode (31) which is formed on the field insulating film (21) and led around as a line such as to intersect the resurf region (20) in a plan view.

[B19] The semiconductor device (101) according to B18, wherein the field electrode (31) is constituted of a field resistance film which is electrically connected to the cathode region (103) and the anode region (105).

[B20] The semiconductor device (101) according to B18 or B19, wherein the field electrode (31) is orthogonal to the resurf region (20) in a plan view.

While the embodiments of the present invention have been described in detail, these are merely specific examples used to clarify the technical contents of the present invention and the present invention should not be interpreted as being limited to these specific examples and the scope of the present invention is to be limited only by the appended claims.

### REFERENCE SIGNS LIST

1 Semiconductor device
2 Semiconductor chip
3 First main surface
11 High potential region
12 Low potential region
13 Drift region
14 Well region
15 Drain region
16 Body region
17 Source region
18 Channel region
20 resurf region
21 Field insulating film
31 Field electrode
40 Gate insulating film
41 Gate electrode
91 Semiconductor device
101 Semiconductor device

1. A semiconductor device comprising:
a semiconductor chip which has a main surface;
a high potential region which is formed in a surface layer portion of the main surface;
a low potential region which is formed in the surface layer portion of the main surface at an interval from the high potential region;
a first conductive type drift region which is formed in a region between the high potential region and the low potential region in the surface layer portion of the main surface; and
a first conductive type resurf region which is formed partially in a surface layer portion of the drift region such as to expose a part of a region which serves as a current path in the drift region from the main surface and which has an impurity concentration higher than that of the drift region.

2. The semiconductor device according to claim 1, wherein
the resurf region is formed as a line extending in a direction in which the high potential region and the low potential region oppose each other.

3. The semiconductor device according to claim 1, wherein
the plurality of resurf regions are formed in the surface layer portion of the drift region at an interval from each other.

4. The semiconductor device according to claim 3, wherein
the plurality of resurf regions are formed in a striped shape extending in a direction in which the high potential region and the low potential region oppose each other and expose a part of the drift region in a striped shape from the main surface.

5. The semiconductor device according to claim 1, further comprising:
a field insulating film which covers the drift region and the resurf region on the main surface, and
a field electrode which is led around as a line on the field insulating film and traverses the resurf region in a plan view.

6. The semiconductor device according to claim 5, wherein
the field electrode traverses the resurf region a plurality of times in a plan view.

7. The semiconductor device according to claim 5, wherein
the field electrode surrounds the high potential region a plurality of times.

8. The semiconductor device according to claim 5, wherein
the field electrode is constituted of a field resistance film which is electrically connected to the high potential region and the low potential region.

9. The semiconductor device according to claim 1, wherein
the high potential region includes a first conductive type drain region which is formed in the surface layer portion of the main surface,
the low potential region includes a second conductive type body region which is formed in the surface layer portion of the main surface and a first conductive type source region which is formed in a surface layer portion of the body region,
the drift region is formed in a region between the drain region and the body region in the surface layer portion of the main surface, and
the resurf region is formed in a region between the drain region and the source region in the surface layer portion of the drift region.

10. The semiconductor device according to claim 9, wherein
the resurf region is connected to the body region.

11. The semiconductor device according to claim 9, wherein
the high potential region includes a first conductive type well region which is formed in the surface layer portion of the main surface and the drain region which is formed in a surface layer portion of the well region, and
the resurf region is formed in a region between the well region and the source region in the surface layer portion of the drift region.

12. The semiconductor device according to claim 11, wherein
the resurf region is connected to the well region.

13. The semiconductor device according to claim 9, wherein
the resurf region is formed only in a region sandwiched between the source region and the drift region in the drift region.

14. The semiconductor device according to claim 9, wherein
the body region surrounds the drain region, and
the source region is formed in a shape having ends in the surface layer portion of the body region.

15. The semiconductor device according to claim 9, further comprising:
a channel region which is formed between the drift region and the source region in the surface layer portion of the body region,
a gate insulating film which covers the channel region on the main surface, and
a gate electrode which is formed on the gate insulating film.

16. The semiconductor device according to claim 15, wherein
the gate insulating film covers the drift region and the resurf region.

17. A semiconductor device comprising:
a semiconductor chip which has a main surface;
a high potential region and a low potential region which are formed in a surface layer portion of the main surface at an interval from each other;
a first conductive type drift region which is formed in a region between the high potential region and the low potential region in the surface layer portion of the main surface;
a first conductive type resurf region which is formed as a line extending in a direction in which the high potential region and the low potential region oppose each other in a surface layer portion of the drift region such as to expose a part of a region which serves as a current path in the drift region from the main surface and which has an impurity concentration higher than that of the drift region;
a field insulating film which covers the drift region and the resurf region; and
a field electrode which is formed on the field insulating film and led around as a line such as to intersect the resurf region in a plan view.

18. The semiconductor device according to claim 17, wherein
the field electrode is constituted of a field resistance film which is electrically connected to the high potential region and the low potential region.

19. The semiconductor device according to claim 17, wherein
the field electrode is orthogonal to the resurf region in a plan view.
